(19) United States
(12) Patent Application Publication
(10) Pub. No.: US 2025/0255018 A1
(43) Pub. Date: Aug. 7, 2025

(54) IMAGE SENSOR

(71) Applicant: Samsung Electronics Co., Ltd., Suwon-si (KR)

(72) Inventors: Jonghyuk WOO, Suwon-si (KR); Min-Sun KEEL, Suwon-si (KR)

(73) Assignee: Samsung Electronics Co., Ltd., Suwon-si (KR)

(21) Appl. No.: 19/029,250

(22) Filed: Jan. 17, 2025

(30) Foreign Application Priority Data
Feb. 6, 2024 (KR) 10-2024-0018421

(51) Int. Cl. H10F 39/00; H04N 25/13; H04N 25/77; H04N 25/79

(52) U.S. Cl. CPC H10F 39/8023; H04N 25/135; H04N 25/77; H04N 25/79; H10F 39/807

(57) ABSTRACT

An image sensor including a pixel group including a plurality of unit pixels, each of the plurality of unit pixels including an infrared pixel including a first photoelectric conversion element (PD); and a non-infrared pixel including a second PD having a smaller light-receiving area than the first PD in a plan view, the non-infrared pixel configured to sense a visible light, a plurality of infrared pixels arranged in a first direction and a second direction perpendicular to the first direction, and the non-infrared pixel disposed diagonally to the infrared pixel in a third direction different from the first and second directions.

### CROSS-REFERENCE TO RELATED APPLICATION

This application is based on and claims ranking under 35 U.S.C. § 119 to Korean Patent Application No. 10-2024-0018421, filed on Feb. 6, 2024 in the Korean Intellectual Property office, the disclosure of which is incorporated by reference herein in its entirety.

### BACKGROUND

The inventive concepts relate to image sensors, and more particularly, to image sensors including pixels in which an infrared filter and a color filter are arranged.

Image sensors, which convert captured images to electrical signals, are used not only in general consumer electronics, such as digital cameras, mobile phone cameras, and portable camcorders, but in cameras mounted on automobiles, security devices, and robots. Image sensors are devices which capture two-dimensional or three-dimensional images of objects.

The image sensors include pixel arrays, and each pixel included in the pixel array may include a photoelectric conversion element. The image sensors generate images of the objects by using photoelectric conversion elements which react according to intensity of light reflected from the objects. Recently, even in low light situations or in no light situations, technology for generating an image of an object using an infrared filter has been developed.

### SUMMARY

The inventive concepts provide image sensor capable of improving the quality of an image even in low light conditions by regularly arranging infrared filters and color filters in each of a plurality of photoelectric conversion elements of pixels.

According to some aspects of the inventive concepts, there is provided an image sensor including a pixel group including a plurality of unit pixels, each of the plurality of unit pixels including an infrared pixel including a first photoelectric conversion element (PD); and a non-infrared pixel including a second PD having a smaller light-receiving area than the first PD in a plan view, wherein the non-infrared pixel is configured to sense a visible light, wherein a plurality of infrared pixels are arranged in a first direction and a second direction perpendicular to the first direction, and wherein the non-infrared pixel is disposed diagonally to the infrared pixel in a third direction different from the first and second directions.

According to some aspects of the inventive concepts, there is provided an image sensor including a pixel group including four unit pixels arranged in a 2×2 matrix, each of unit pixels in the four unit pixels including an infrared pixel including a first photoelectric conversion element (PD); a non-infrared pixel including a second PD having a smaller light-receiving area than the first PD in a plan view, wherein the four unit pixels including a first unit pixel; a second unit pixel disposed directly adjacent to the first unit pixel in a first direction; a third unit pixel disposed directly adjacent to the first unit pixel in a second direction; and a fourth unit pixel disposed directly adjacent to the second unit pixel in the second direction, wherein the non-infrared pixel is disposed diagonally to the infrared pixel in a third direction different from the first and second directions, wherein the non-infrared pixel in the first unit pixel is configured to transmit a first color to the second PD in the first unit pixel, wherein the non-infrared pixel in the second unit pixel is configured to transmit a second color to the second PD in the second unit pixel, and wherein the second color is different from the first color.

In addition, according to some aspects of the inventive concepts, there is provided an image sensor including a first sub-pixel group including four unit pixels arranged in a 2×2 matrix, each of unit pixels in the four unit pixels including 2×2 a first infrared pixel including a first photoelectric conversion element (PD); a first non-infrared pixel including a second PD having a smaller light-receiving area than the first PD in a plan view, wherein the four unit pixels including a first unit pixel; a second unit pixel disposed directly adjacent to the first unit pixel in a first direction; a third unit pixel disposed directly adjacent to the first unit pixel in a second direction; and a fourth unit pixel disposed directly adjacent to the second unit pixel in the first direction, wherein the first non-infrared pixel is disposed diagonally to the first infrared pixel in a third direction different from the first and second directions, and wherein the first non-infrared pixels in the first to fourth unit pixels are configured to transmit a first color to the second PDs of the first to fourth unit pixels.

### BRIEF DESCRIPTION OF THE DRAWINGS

Embodiments will be more clearly understood from the following detailed description taken in conjunction with the accompanying drawings in which:

FIG. 1 is a block diagram of an image sensor according to some example embodiments;

FIG. 2 is a circuit diagram of a pixel according to some example embodiments;

FIG. 3 is a diagram of a pixel array according to some example embodiments;

FIG. 4 is a cross-sectional view of the pixel array of FIG. 3 taken along direction I-I′;

FIG. 5A is a diagram of a pixel array having a Bayer pattern according to some example embodiments;

FIG. 5B is a cross-sectional view of the pixel array of FIG. 5A taken along direction I-I′;

FIG. 5C is a diagram of a pixel array including a yellow color filter and a cyan color filter according to some example embodiments;

FIG. 5D is a diagram of a pixel array including a white layer and a green color filter according to some example embodiments;

FIG. 5E is a diagram of a pixel array including a white layer and a blue color filter according to some example embodiments;

FIG. 6A is a diagram of a pixel array having a red-green-blue-white (RGBW) pattern according to some example embodiments;

FIG. 6B is a diagram of a pixel array having a red-green-blue-yellow (RGBY) pattern according to some example embodiments;

FIG. 7A is a diagram of a pixel array including pixel groups according to some example embodiments;

FIG. 7B is a diagram of a pixel array including pixel groups according to some example embodiments;

FIG. 8A is a diagram of a pixel group including 6×6 pixels according to some example embodiments;

FIG. 8B is a diagram of a pixel group including 6×6 pixels according to some example embodiments;

FIG. 9 is a diagram of a pixel group including 8×8 pixels according to some example embodiments;

FIG. 10 is a diagram of a pixel array including an infrared pixel and a color pixel according to some example embodiments;

FIG. 11A is a diagram of a pixel group including an infrared pixel and a color pixel according to some example embodiments;

FIG. 11B is a diagram of a pixel group including an infrared pixel and a color pixel according to some example embodiments;

FIG. 12A is a diagram of a pattern, in which infrared pixels are diagonally arranged, according to some example embodiments;

FIG. 12B is a diagram of a pattern, in which infrared pixels are diagonally arranged, according to some example embodiments;

FIG. 13A is a diagram illustrating that infrared pixels are included in a pixel group, according to some example embodiments;

FIG. 13B is a diagram of a pixel group including 4×4 pixels according to some example embodiments;

FIG. 14A is a diagram of a pixel array including pixel groups according to some example embodiments;

FIG. 14B is a diagram of a pixel array including a yellow color filter according to some example embodiments;

FIG. 14C is a diagram of a pixel array including a white layer according to some example embodiments;

FIG. 15 is a diagram of a pixel array including sub-pixel groups according to some example embodiments; and

FIG. 16 is a block diagram of an electronic device according to some example embodiments.

### DETAILED DESCRIPTION

Hereinafter, embodiments of the inventive concepts will be described in detail with reference to the accompanying drawings. Identical reference numerals are used for the same constituent elements in the drawings, and duplicate descriptions thereof are omitted.

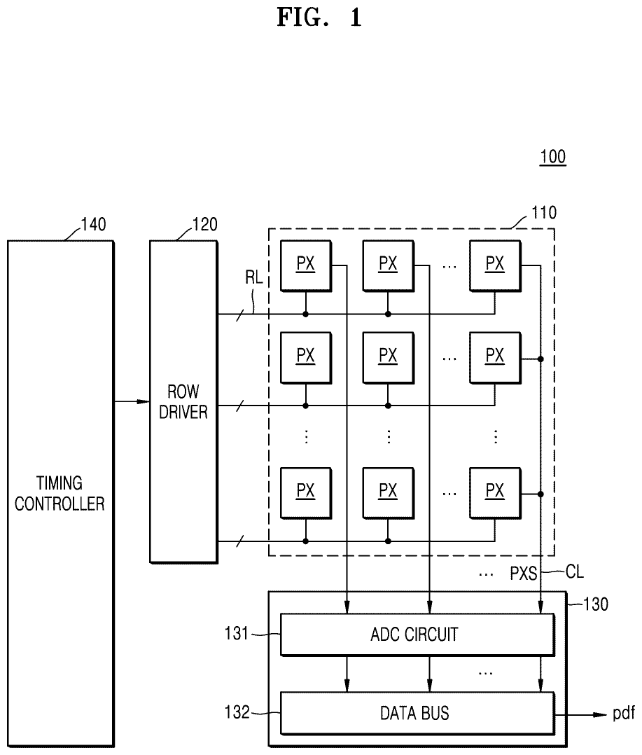

FIG. 1 is a block diagram of an image sensor 100 according to some example embodiments.

The image sensor 100 may be mounted on an electronic device having an image or light sensing function. For example, the image sensor 100 may be mounted on an electronic device, such as a camera, a smartphone, a wearable device, an Internet of Things (IoT) device, home appliance devices, a personal computer (PC), a personal digital assistant (PDA), a portable multimedia player (PMP), a navigation device, a drone, and an advanced drivers assistance system (ADAS). In addition, the image sensor 100 may be mounted on an electronic device provided as a component of vehicles, furniture, manufacturing devices, doors, various measuring devices, etc.

Referring to FIG. 1, the image sensor 100 may include a pixel array 110, a row driver 120, a readout circuit 130, and a timing controller 140, and the readout circuit 130 may include an analog-to-digital conversion circuit 131 (hereinafter, referred to as an ADC circuit) and a data bus 132.

The pixel array 110 may be connected to a plurality of row lines RL, and a plurality of column lines CL and may include a plurality of pixels PX arranged in an array. The plurality of pixels PX may include active pixel sensors (APSs).

Each of the plurality of pixels PX may include at least one photoelectric conversion element, and the pixel PX may detect light by using the photoelectric conversion element and output an image signal, which is an electrical signal according to sensed light. For example, the photoelectric conversion element may include a photo-sensing element including an organic material or an inorganic material, such as an inorganic photo diode, an organic photodiode, a Perovskite photodiode, a photo transistor, a photogate, and a pinned photodiode. In some example embodiments, each of the plurality of pixels PX may include a plurality of photoelectric conversion elements.

On the other hand, microlenses for condensation may be arranged on an upper portion of each of the plurality of pixels PX or on each of pixel groups including adjacent pixels PX. Each of the plurality of pixels PX may detect light in a particular spectrum range from light received by the microlens. For example, the pixel array 110 may include a red pixel converting light in a red spectrum range into an electric signal, a green pixel converting light in a green spectrum range into an electric signal, and a blue pixel converting light in a blue spectrum range into an electric signal. However, the example embodiments are not limited thereto, and the pixel array 110 may include pixels converting light from other spectrum ranges, except for red, green, and blue light, into electrical signals.

In some example embodiments, the plurality of pixels PX may have a multi-layer structure. The pixel PX having a multi-layer structure may include a stacked plurality of photoelectric conversion elements, which convert light in different spectrum ranges into electrical signals, and may generate electrical signals corresponding to different colors from the plurality of photoelectric conversion elements. In other words, the electrical signals respectively corresponding to a plurality of colors may be output by one pixel PX.

A filter array for transmitting light in an infrared ray region and light in a visible ray region may be arranged on the plurality of pixels PX. The type of light that may be detected by a corresponding pixel may be determined according to the type of filter arranged on each of the plurality of pixels. When an infrared filter for transmitting light in the infrared region is arranged on a particular pixel, the corresponding pixel may detect light in the infrared region and convert the light in the infrared region into an electrical signal.

When a color filter for transmitting light in the visible ray region is arranged on the particular pixel, the corresponding pixel may detect light in the visible ray region and convert the light in the visible ray region into an electrical signal. A color that may be detected by the corresponding pixel may be determined according to a color filter arranged on the particular pixel. However, the example embodiments are not limited thereto, and in some example embodiments, in the case of a particular photoelectric conversion element, light in a particular wavelength band may also be converted into an electrical signal according to the level of the electrical signal applied to the photoelectric conversion element.

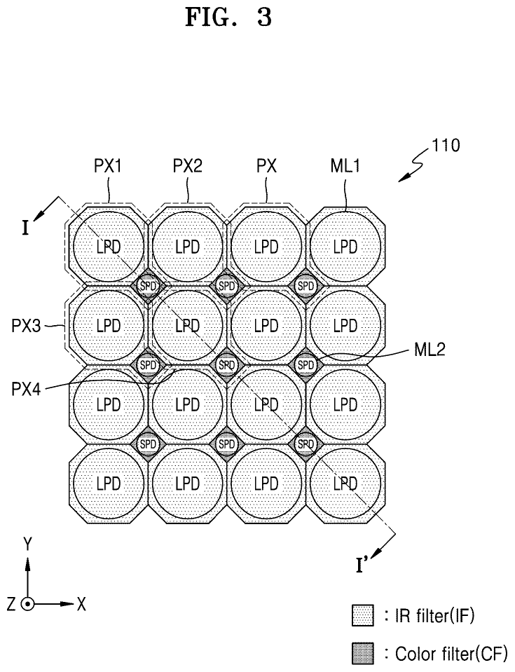

In some example embodiments, each of the plurality of pixels PX may include at least two photodiodes configured to be exposed to a light source. For example, the pixel PX may include a first photoelectric conversion element having a relatively large light-receiving area and a second photoelectric conversion element having a relatively small light-receiving area. The first photoelectric conversion element may be referred to as a first photodiode (for example, a first photodiode LPD in FIG. 3), and the second photoelectric conversion element may be referred to as a second photodiode (for example, a second photodiode SPD in FIG. 3). The first photoelectric conversion element may be referred to as a large photodiode, and the second photoelectric conversion element may be referred to as a small photodiode. In this manner, a structure, in which the first photodiode LPD and the second photodiode SPD are included in one pixel PX, may be referred to as a split photodiode. On the other hand, the example embodiments are not limited thereto, and the structure described above may be referred to as another name.

Because the light-receiving area of the first photodiode LPD is large, the first photodiode LPD may generate more charges than the second photodiode SPD under the same light-receiving conditions. In other words, the first photodiode LPD may have higher sensitivity than the second photodiode SPD. For example, the first photodiode LPD may generate a pixel signal PXS corresponding to low illuminance and the second photodiode SPD may generate the pixel signal PXS corresponding to high illuminance. However, the example embodiments are not limited thereto, and the first photodiode LPD may generate the pixel signal PXS corresponding to both low illuminance and high illuminance and the second photodiode SPD may generate the pixel signal PXS corresponding to both low illuminance and high illuminance. Hereinafter, for convenience of explanation, it is assumed that the pixel PX includes the first photodiode LPD and the second photodiode SPD.

In some example embodiments, each of the plurality of pixels PX may include an infrared filter, which is arranged on the first photoelectric conversion element and transmits light in the infrared ray region to the first photoelectric conversion element, and a color filter, which is arranged on the second photoelectric conversion element and transmits light in the visible ray region to the second photoelectric conversion element. In other words, in each of the plurality of pixels PX, the infrared filter may be arranged on the first photodiode LPD and the color filter may be arranged on the second photodiode SPD. The first photodiode LPD may detect light in the infrared ray region, and the second photodiode SPD may detect light in the visible ray region. However, the example embodiments are not necessarily limited thereto, and the color filter may be arranged on the first photodiode LPD and the infrared filter may be arranged on the second photodiode SPD. The first photodiode LPD may detect light in the visible ray region, and the second photodiode SPD may detect light in the infrared ray region.

The second photodiode SPD may detect light in a particular visible ray region. In the second photodiode SPD, a color that may be detected by the second photodiode SPD may be determined according to the color of the color filter arranged thereon. There may be various types of color filters arranged on the second photodiode SPD. For example, the color filter may include a red color filter, a green color filter, and a blue color filter. However, the example embodiments are not limited thereto, and the color filter may include color filters that transmit light in other spectrum ranges except for red, green, and blue colors. For example, the color filter may include color filters for sensing yellow, cyan, and magenta colors. Alternatively, the color filter may include a white layer sensing a white color.

The color filter of a particular color may be arranged in a particular pattern or a particular rule in the second photodiode SPD included in the pixel array 110. For example, the pixel group may include first through fourth pixels, each including the first photodiode LPD and the second photodiode SPD. The pixel groups may be repeatedly arranged in the pixel array 110. A first color filter may be arranged on the second photodiode SPD included in the first pixel, a second color filter may be arranged on the second photodiode SPD included in the second pixel, a third color filter may be arranged on the second photodiode SPD included in the third pixel, and a fourth color filter may be arranged on the second photodiode SPD included in the fourth pixel.

In some example embodiments, the colors of the first color filter, the second color filter, the third color filter, and the fourth color filter may be different. For example, the first color filter may include the red color filter, the second color filter may include the green color filter, the third color filter may include the blue color filter, and the fourth color filter may include the white layer. However, the example embodiments are not limited thereto.

In some example embodiments, the colors of the second color filter and the third color filter among the colors of the first color filter, the second color filter, the third color filter, and the fourth color filter may be the same. For example, the first color filter may include the red color filter, the second color filter may include the green color filter, the third color filter may include the green color filter, and the fourth color filter may include the blue color filter. However, the example embodiments are not limited thereto, and some example embodiments may vary such that the first color filter may include the red color filter, the second color filter may include a yellow color filter, the third color filter may include the yellow color filter, the fourth color filter may include a cyan color filter.

In some example embodiments, the pixel array 110 may include the pixel groups, and each of the pixel groups may include the infrared pixel and the color pixel. Each of the pixel groups may include at least one infrared pixel and at least one color pixel. The infrared pixels and the color pixels may be arranged in the pixel array 110 in a particular pattern. For example, the infrared pixels and the color pixels may be alternately arranged in an array in the pixel array 110. However, the example embodiments are not necessarily limited thereto, and the infrared pixels and the color pixels may form a particular pattern and may be variously arranged. Because the infrared filter and the color filter are included in one pixel PX, the photoelectric conversion efficiency may be improved, the high dynamic range may be improved, and the quality of the image may be improved. A structure, in which the infrared pixel and the color pixel are arranged, is described below with reference to FIG. 3 and thereafter.

Each of the infrared pixel and the color pixel may include the first photoelectric conversion element and the second photoelectric conversion element. The infrared pixel may include a first filter arranged on the first photoelectric conversion element of the infrared pixel, and a second filter arranged on the second photoelectric conversion element of the infrared pixel. The first filter may include the infrared filter which absorbs light in the infrared ray region. The second filter may include the color filter which absorbs light in the visible ray region. The infrared pixel may mean a pixel in which the infrared filter is arranged on the first photoelectric conversion element (the first photodiode LPD).

The color pixel may include a third filter arranged on the first photoelectric conversion element of the color pixel and a fourth filter arranged on the second photoelectric conversion element of the color pixel. The third filter may include the color filter which absorbs light in the visible ray region. The fourth filter may include a filter which absorbs light in the infrared ray region and light in the visible ray region. The fourth filter may include one of the color filter and the infrared filter. The color pixel may mean a pixel in which the color filter is arranged on the first photoelectric conversion element (the first photodiode LPD). The color filter or the infrared filter may be arranged on the second photoelectric conversion element (the second photodiode SPD) of the color pixel. In each of the plurality of pixels PX, charge generated by the photoelectric conversion element such as a photodiode may be accumulated at a floating diffusion node, and the charge accumulated in the floating diffusion node may be converted into a voltage. In this case, the rate at which the charge accumulated in the floating diffusion node is converted into a voltage may be referred to as a conversion gain. The conversion gain may vary according to the capacitance of the floating diffusion node.

When the capacitance of the floating diffusion node increases, the conversion gain may decrease, and when the capacitance of the floating diffusion node decreases, the conversion gain may increase. In some example embodiments, each of the plurality of pixels PX may operate at a dual conversion gain. The dual conversion gain may include a low conversion gain LCG and a high conversion gain HCG. Because the high conversion gain HCG has a higher rate at which the charge is converted into a voltage, it may be applied to an operation of generating the pixel signal PXS corresponding to a lower illuminance than the low conversion gain LCG. Hereinafter, for convenience of explanation, an operation mode of generating the pixel signal PXS by using a high conversion gain HCG may be referred to as a high conversion gain HCG mode, and an operation mode of generating a pixel signal PXS by using a low conversion gain LCG may be referred to as a low conversion gain LCG mode. In some example embodiments, each of the first photodiode LPD and the second photodiode SPD may generate the pixel signals PXS in the dual conversion gain mode described above.

In some example embodiments, the pixel signals PXS generated by the first photodiode LPD and the second photodiode SPD may be individually separated. For example, a first pixel signal may be generated by using the first photodiode LPD, and first image data may be generated from the first pixel signal. A second pixel signal may be generated by using the second photodiode SPD, and second image data may be generated from the second pixel signal. In some example embodiments, the image sensor 100 may be mounted on an electronic device provided in a vehicle. The image sensor 100 may be used to generate an image of the interior of the vehicle. For example, the image sensor 100 may be used to generate an image of a driver and/or passenger in the vehicle. The electronic device provided in the vehicle may recognize the driver based on the first image data generated by using the first photodiode LPD and may recognize the passenger based on the second image data generated by using the second photodiode SPD.

However, the example embodiments are not limited thereto, and the pixel signal PXS generated by using the first photodiode LPD and the second photodiode SPD may be synthesized into one image, and the synthesized image may have a high dynamic range. For example, the electronic device provided in the vehicle may recognize the driver and the passenger based on one image data generated by using the first photodiode LPD and the second photodiode SPD.

The row driver 120 may drive the pixel array 110 in units of rows. The row driver 120 may decode a row control signal (for example, an address signal) received from the timing controller 140 and select at least one of the row lines constituting the pixel array 110 in response to the decoded row control signal. For example, the row driver 120 may generate a selection signal selecting one of a plurality of rows. In addition, the pixel array 110 may output the pixel signal PXS from the row selected by the selection signal provided by the row driver 120. The row driver 120 may transmit the control signals for outputting the pixel signal PXS to the pixel array 110, and the pixel PX may output the pixel signal PXS by operating in response to the control signals. For example, the row driver 120 may generate control signals for controlling the pixel PX to output the pixel signal PXS during a readout period and provide the generated control signals to the pixel array 110.

The readout circuit 130 may read out the pixel signal PXS from the pixels PX on a row selected by the row driver 120, among the plurality of pixels PX. In this case, the pixel signal PXS may include a reset signal or an image signal (or a sensing signal). The readout circuit 130 may generate and output pixel values pdf corresponding to the plurality of pixels PX in row units, by converting the reset signals and the image signals, which are received from the pixel array 110 via the plurality of column lines CL, into digital data based on a ramp signal from a ramp signal generator. The image data may include pixel values pdf.

The ADC circuit 131 may include a plurality of ADCs respectively corresponding to the plurality of column lines CL, and each of the plurality of ADCs may compare each of the reset signal and the image signal received via the corresponding column line CL with the ramp signal and generate the pixel values pdf based on the comparison results. For example, the ADC may remove the reset signal from the image signal and generate the pixel value pdf indicating the amount of light sensed by the pixel PX.

A plurality of pixel values pdf generated by the ADC circuit 131 may be output as the image data via the data bus 132. For example, the image data may be provided to an image signal processor inside or outside the image sensor 100.

The data bus 132 may output the pixel value pdt output by the ADC circuit 131 after temporarily storing the pixel value pdf. The data bus 132 may include a plurality of column memories and a column decoder. The plurality of pixel values pdf respectively stored in the plurality of column memories may be output as image data under control of the column decoder.

The ADC circuit 131 may include a plurality of correlated double sampling (CDS) circuits (not illustrated) and a plurality of counter circuits (not illustrated). The ADC circuit 310 may convert the pixel signal PXS input by the pixel array 110 to the pixel value pdf, which is a digital signal. Each pixel signal PXS received via each of the plurality of column lines CL may be converted into a pixel value pdf, which is a digital signal, by the CDS circuit and the counter circuit.

The CDS circuit may compare the pixel signal PXS received via the column line CL with the ramp signal and output the comparison result. The CDS circuit may, when a level of the ramp signal is the same as a level of the pixel signal, output the comparison signal which is transitioned from a first level (for example, logic high) to a second level (for example, logic low). A time point, at which a level of the comparison signal is transitioned, may be determined according to the level of the pixel signal PXS.

The CDS circuit may sample and hold the pixel signal PXS provided by the pixel PX according to the CDS method, double sample a level of particular noise (for example, the reset signal) and a level according to the image signal, and generate a comparison signal based on a level corresponding to the difference between the levels.

In some example embodiments, the CDS circuit may include one or more comparators. The comparator may be implemented as, for example, an operational transconductance amplifier (OTA) (or a differential amplifier).

According to some example embodiments, the image sensor 100 may include a signal processor. The signal processor may perform, on the image data, a noise reduction process, a gain adjustment process, a waveform shaping process, an interpolation process, a white balance process, a gamma process, an edge emphasization process, a binning process, etc. In some example embodiments, the signal processor may be provided in a processor outside the image sensor 100.

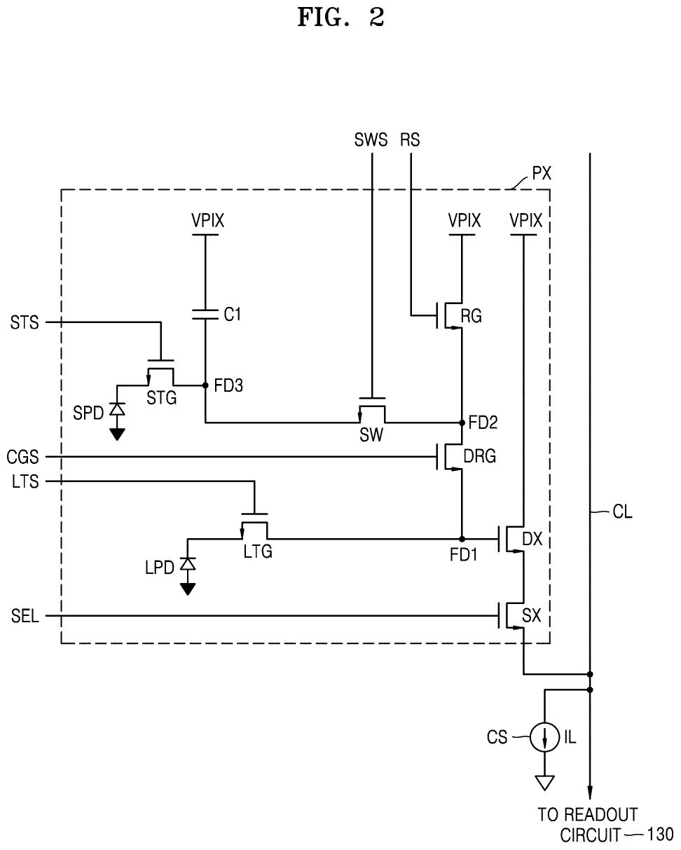

FIG. 2 is a circuit diagram of the pixel PX according to some example embodiments. Duplicate descriptions given with reference to FIG. 1 are omitted.

Hereinafter, the first photoelectric conversion element may be referred to as the first photodiode LPD and the second photoelectric conversion element may be referred to as the second photodiode SPD. The pixel PX may include a plurality of photodiodes, for example, the first photodiodes LPD and the second photodiodes SPD. The pixel PX may further include a first transfer gate LTG, a second transfer gate STG, a reset transistor RG, a driving transistor DX, a selection transistor SX, a gain control transistor DRG, and a switch transistor SW. The reset transistor RG, the gain control transistor DRG, the driving transistor DX, and the selection transistor SX may be disposed on a different chip from the first photodiodes LPD and the second photodiodes SPD. The pixel PX may further include a plurality of floating diffusion regions, for example, first through third floating diffusion regions FD1 through FD3. The pixel PX may further include a capacitor C1.

The first photodiode LPD and the second photodiode SPD may generate a positive photocharge corresponding to the intensity of incident light. For example, the photocharge may include an electron and a hole. The first photodiode LPD and the second photodiode SPD may have different sensitivities. For example, the sensitivity of the first photodiode LPD may be higher than the sensitivity of the second photodiode SPD.

A first source/drain of the first transfer gate LTG may be connected to the first photodiode LPD, and a second source/drain of the first transfer gate LTG may be connected to a first floating diffusion region FD1. The first transfer gate LTG may transmit the photocharge generated by the first photodiode LPD to the first floating diffusion region FD1 in response to a first transfer control signal LTS.

The first source/drain of the gain control transistor DRG may be connected to the first floating diffusion region FD1, and the second source/drain of the gain control transistor DRG may be connected to a second floating diffusion region FD2. A conversion gain transistor DRG may be turned on or off according to a conversion gain signal CGS. When the conversion gain transistor DRG is turned on, the first floating diffusion region FD1 and the second floating diffusion region FD2 may be connected to each other. As the first floating diffusion region FD1 and the second floating diffusion region FD2 are connected to each other, capacitance may increase. When the capacitance increases, the conversion gain may decrease. To the contrary, when the conversion gain transistor DRG is turned off, the first floating diffusion region FD1 and the second floating diffusion region FD2 may be separated from each other, capacitance may be reduced, and thus, the conversion gain may increase. In this case, the conversion gain may mean the ratio at which the charge accumulated in the floating diffusion region is converted into a voltage, and as the capacitance increases, the conversion gain may decrease.

The first source/drain of the second transfer gate STG may be connected to the second photodiode SPD, and the second source/drain of the second transfer gate STG may be connected to a third floating diffusion region FD3. The second transfer gate STG may transmit the photocharge generated by the second photodiode SPD to the third floating diffusion region FD3 in response to the second transmission control signal STS.

A first electrode of the capacitor C1 may be connected to the third floating diffusion region FD3, and a second electrode of the capacitor C1 may be connected to a pixel voltage VPIX. In some example embodiments, a voltage other than the pixel voltage VPIX may be applied to the second electrode of the capacitor C1. The photocharge generated by the second photodiode SPD and overflowed therefrom may be accumulated in the capacitor C1.

The first source/drain of the switch transistor SW may be connected to the second floating diffusion region FD2, and the second source/drain of the switch transistor SW may be connected to the third floating diffusion region FD3. The switch transistor SW may connect the second floating diffusion region FD2 to the third floating diffusion region FD3 in response to a switch control signal SWS.

A reset voltage (for example, the pixel voltage VPIX) may be applied to the first source/drain of the reset transistor RG, and the second source/drain of the reset transistor RG may be connected to the second floating diffusion region FD2. The reset transistor RG may reset the photocharge accumulated in at least one of the first through third floating diffusion regions FD1 through FD3 in response to a reset control signal RS. In some example embodiments, the reset voltage may not be the same as the pixel voltage VPIX.

The first source/drain of the driving transistor DX may be connected to the selection transistor SX, and a driving voltage (for example, the pixel voltage VPIX) may be applied to the second source/drain of the driving transistor DX. The driving transistor DX may operate as a source follower based on a bias current IL generated by a current source CS connected to the column line CL. The driving transistor DX may output a voltage corresponding to the amount of the photocharge accumulated in at least one of the first through third floating diffusion regions FD1 through FD3.

The first source/drain of the selection transistor SX may be connected to the driving transistor DX, and the second source/drain of the selection transistor SX may be connected to the column line CL. The selection transistor SX may output the pixel signal PXS including the reset signal or the image signal to the column line CL in response to a selection signal SEL.

In some example embodiments, the pixel PX may include the infrared pixel. The first filter may be arranged above the first photodiode LPD, and the second filter may be arranged above the second photodiode SPD. The first filter may include the infrared filter which absorbs light in the infrared ray region. The second filter may include the color filter which absorbs light in the visible ray region. In some example embodiments, the plurality of pixels PX included in a pixel array (for example, the pixel array 110 in FIG. 1) may include the infrared pixels.

In some example embodiments, the pixel PX may include the color pixel. The third filter may be arranged above the first photodiode LPD, and the fourth filter may be arranged above the second photodiode SPD. The third filter may include the color filter. The fourth filter may include one of the color filter and the infrared filter. In some example embodiments, a pixel array may include an infrared pixel and a color pixel, and the infrared pixel and the color pixel may be arranged in a particular pattern.

FIG. 3 is a diagram of a pixel array 110 according to some example embodiments. FIG. 3 illustrates an implementation example of a pixel array corresponding to an infrared (IR) filter IF and a color filter CF according to some example embodiments. Because the pixel array 110 of FIG. 3 corresponds to the pixel array 110 in FIG. 1, duplicate descriptions thereof are omitted.

Referring to FIG. 3, the pixel array 110 may include the plurality of pixels PX. The pixel array 110 may include the plurality of pixels PX arranged in a first direction and a second direction. For example, the first direction may include the X-axis direction and the second direction may include the Y-axis direction. Each of the plurality of pixels PX may include a plurality of photodiodes. The pixel PX may include the first photodiode LPD and the second photodiode SPD. For example, a pixel signal (for example, the pixel signal PXS in FIG. 1) generated by each of the first photodiode LPD and the second photodiode SPD may be output to the readout circuit (for example, the readout circuit 130 in FIG. 1). In FIG. 3, the first photodiode LPD is illustrated as an octagon and the second photodiode SPD is illustrated as a square. However, this is for convenience of drawing and corresponds to an example, and the first photodiode LPD and the second photodiode SPD may have various shapes.

The pixel array 110 may further include a filter so that the pixels PX may sense light in the IR ray region and light in the visible ray region. As an example, the first photodiode LPD may sense light in the IR ray region and the second photodiode SPD may sense light in the visible ray region. The pixel PX may include the IR pixel, the IR filter IF may be arranged above the first photodiode LPD, and the color filter CF may be arranged above the second photodiode SPD. For example, the IR filter IF may be arranged above the first photodiode LPD in a third direction. For example, the third direction may be the Z-axis direction. The color filter CF may be arranged above the second photodiode SPD in the third direction. The color filter CF may transmit various colors to the second photodiode SPD.

The color filter CF of the pixel array 110 may include the color filter CF which senses various colors, and may be arranged to form various patterns. The color filter CF may be arranged in various manners according to the use and characteristics of the image sensor (for example, the image sensor 100 of FIG. 1).

In some example embodiments, the pixel array 110 may include pixel groups including a first pixel PX1, a second pixel PX2, a third pixel PX3, and a fourth pixel PX4, and colors of color filters CF included in the first pixel PX1, the second pixel PX2, the third pixel PX3, and the fourth pixel PX4 may be different from each other. The first pixel PX1 may include the first color filter CF, the second pixel PX2 may include the second color filter CF, the third pixel PX3 may include the third color filter CF, and the fourth pixel PX4 may include the fourth color filter CF. The colors of the first color filter CF, the second color filter CF, the third color filter CF, and the fourth color filter CF may be different from each other.

In some example embodiments, colors of color filters CF included in the second pixel PX2 and the third pixel PX3 may be the same. The second pixel PX2 may be arranged or spaced from the first pixel PX1 in the first direction, the third pixel PX3 may be arranged or spaced from the first pixel PX1 in the second direction perpendicular to the first direction, and the fourth pixel PX4 may be arranged or spaced from the third pixel PX3 in the first direction. The colors of the second color filter CF of the second pixel PX2 and the third color filter CF of the third pixel PX3 may be the same.

The pixel array 110 may include a plurality of pixel groups including 2n (n is a positive integer of 2 or more) X 2n pixels PX, and each of the plurality of pixel groups may include first through fourth sub-pixel groups each including n×n pixels PX. The color filters CF of the pixels PX included in one sub-pixel group may be the same color. In some example embodiments, the pixels PX included in a first sub-pixel group may include the first color filter CF, the pixels PX included in a second sub-pixel group may include the second color filter CF, the pixels PX included in a third sub-pixel group may include the third color filter CF, the pixels PX included in a fourth sub-pixel group may include the fourth color filter CF, and the colors of the first color filter CF, the second color filter CF, the third color filter CF, and the fourth color filter CF may be different from each other. In some example embodiments, the colors of the first color filter CF, the second color filter CF, and the fourth color filter CF may be different from each other, and the colors of the second color filter CF and the third color filter CF may be the same.

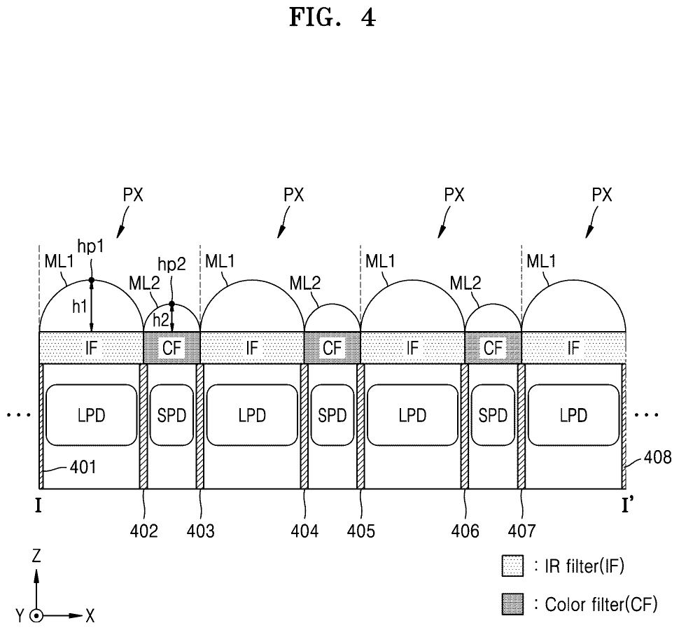

The pixel array 110 may further include a microlens for condensing the pixels PX. For example, a first microlens ML1 may be arranged above the first photodiode LPD and a second microlens ML2 may be arranged above the second photodiode SPD. The first microlens ML1 and the second microlens ML2 are described in detail with reference to FIG. 4.

Although FIG. 3 illustrates that the pixel array 110 includes 16 pixels PX, the illustration is for convenience of description, and the pixel array 110 may include more than 16 pixels PX. In addition, although FIG. illustrates that all of the pixels PX included in the pixel array 110 are infrared pixels, the example embodiments are not necessarily limited thereto, and the pixel array 110 may also include both infrared pixels and color pixels.

In the image sensor 100 of the inventive concepts, by arranging an infrared filter above the first photodiode LPD having a large light-receiving area, the photoelectric conversion efficiency may be improved. In addition, as the infrared filter and the color filter are included in one pixel, the photoelectric conversion efficiency may be improved, while the high dynamic range is improved and the quality of the image is improved.

FIG. 4 is a cross-sectional view of the pixel array 110 of FIG. 3 taken along direction I-I′. Duplicate descriptions given above are omitted.

Referring to FIG. 4, a cross-sectional view is illustrated in which the infrared filter IF and the color filter CF are respectively arranged above the first photodiode LPD and the second photodiode SPD. The plurality of pixels included in the pixel array of the inventive concepts may have a Deep Trench Isolation (DTI) structure. For example, the first photodiode LPD and the second photodiode SPD may be fully isolated by at least one isolation layer 402, 404, 406, 408 that contacts both of an upper and lower surfaces of the substrate (the upper surface opposing the lower surface of the substrate), or they may be partially isolated by at least one isolation layer that contacts only the lower surface of the substrate (not contact the upper surface of the substrate). Similarly, adjacent pixels may also be fully isolated by at least one isolation layer 401, 403, 405, 407 that contacts both of the upper and lower surfaces of the substrate, or partially isolated by at least one isolation layer that contacts only the lower portion (not contact the upper surface of the substrate). In addition, referring to FIG. 4, a cross-sectional view is illustrated in which the first microlens ML1 is arranged on the infrared filter IF and the second microlens ML2 is arranged on the color filter CF.

The first microlens ML1 may be arranged above the first photodiode LPD. The infrared filter IF may be arranged above the first photodiode LPD, and the first microlens ML1 may be arranged on the infrared filter IF. The second microlens ML2 may be arranged above the second photodiode SPD. The color filter CF may be arranged above the second photodiode SPD, and the second microlens ML2 may be arranged above the color filter CF.

Highest points of the first microlens ML1 and the second microlens ML2 in the direction from the first photodiode LPD toward the infrared filter IF may be different. The highest point of the first microlens ML1 may be different from the highest point of the second microlens ML2. A direction from the first photodiode LPD toward the infrared filter IF may be a third direction. For example, a direction from the infrared filter IF toward the first microlens ML1, a direction from the second photodiode SPD toward the color filter CF, and a direction from the color filter CF toward the second microlens ML2 may be the same as the third direction. The third direction may be perpendicular to the first direction. For example, the first direction may be the X-axis direction and the third direction may be the Z-axis direction.

The highest point of a microlens ML may mean the position of the point at which the microlens ML has the greatest height in the Z-axis direction. The highest point of the first microlens ML1 may be a first highest point hp1, and the height of the first highest point hp1 may be a first height h1. The highest point of the second microlens ML2 may be a second highest point hp2, and the height of the second highest point hp2 may be a second height h2. The first height h1 may be different from the second height h2.

The highest point of the first microlens ML1 may be higher than the highest point of the second microlens ML2. For example, the first height h1 of the first highest point hp1 may be higher than the second height h2 of the second highest point hp2. Because the highest point of the first microlens ML1 arranged above the first photodiode LPD is high, the condensation capability of the first photodiode LPD may be improved and the quality and reliability of the image may be improved.

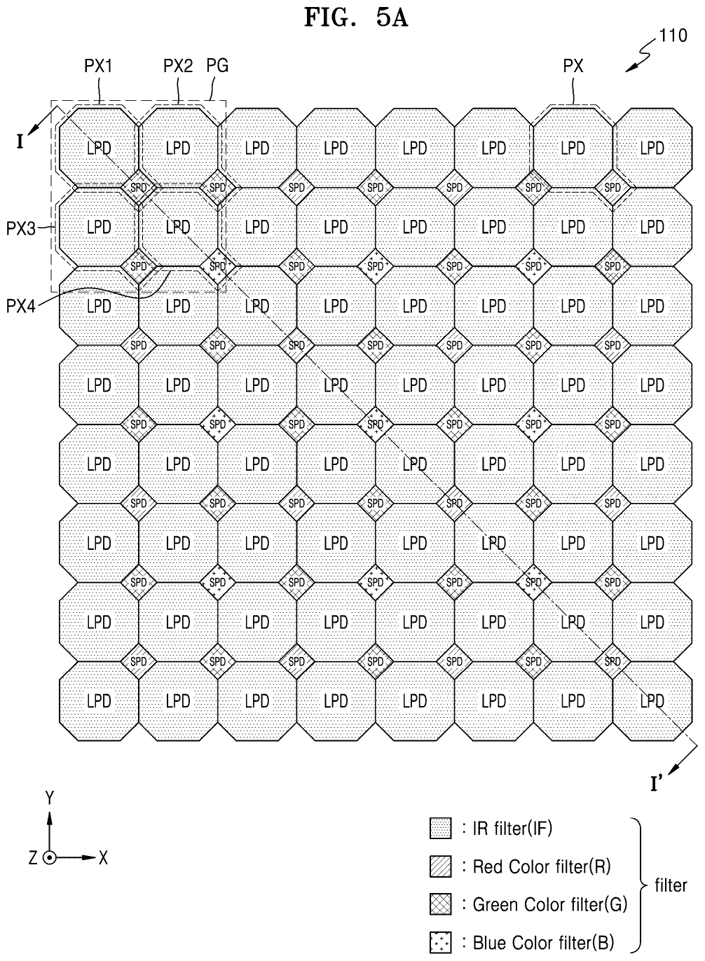

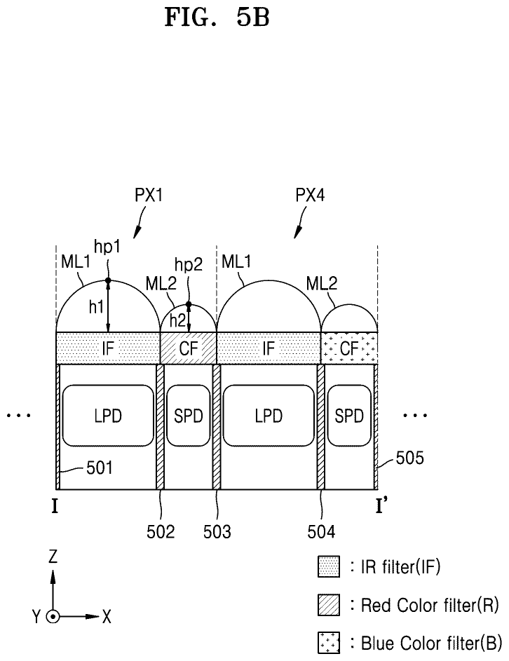

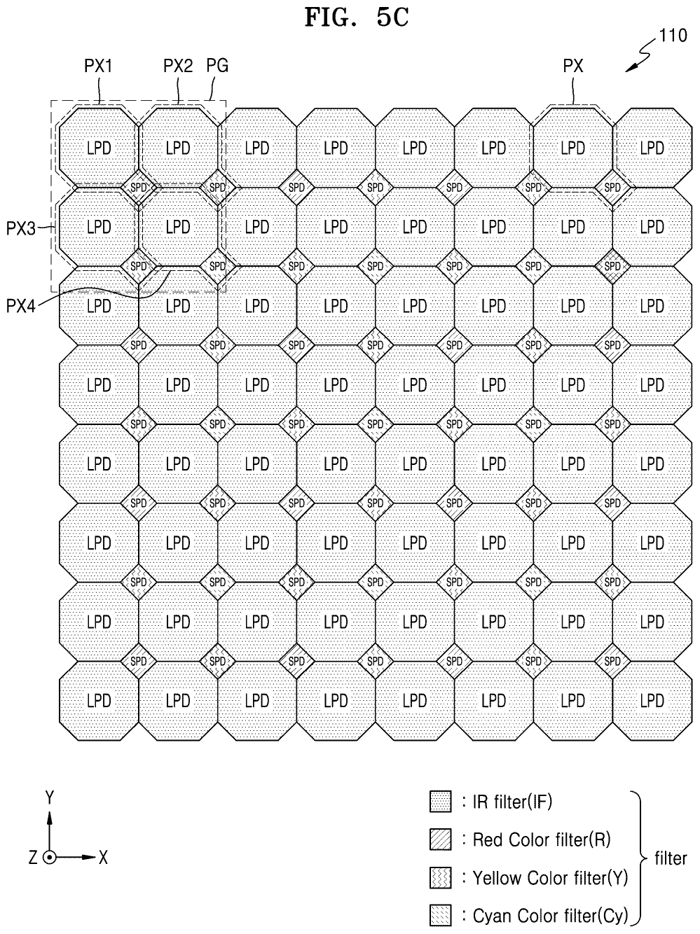

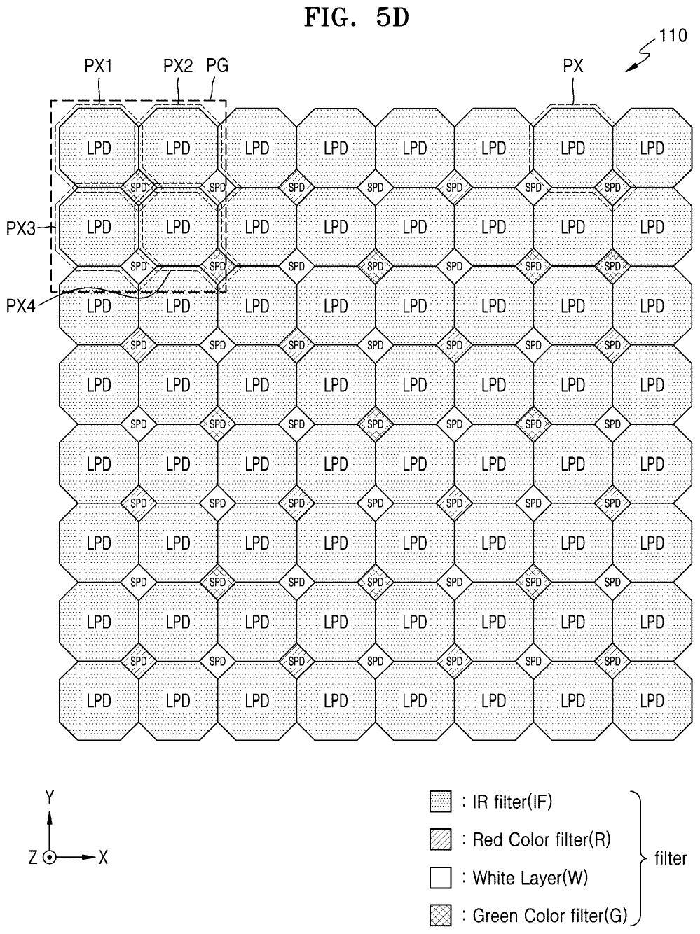

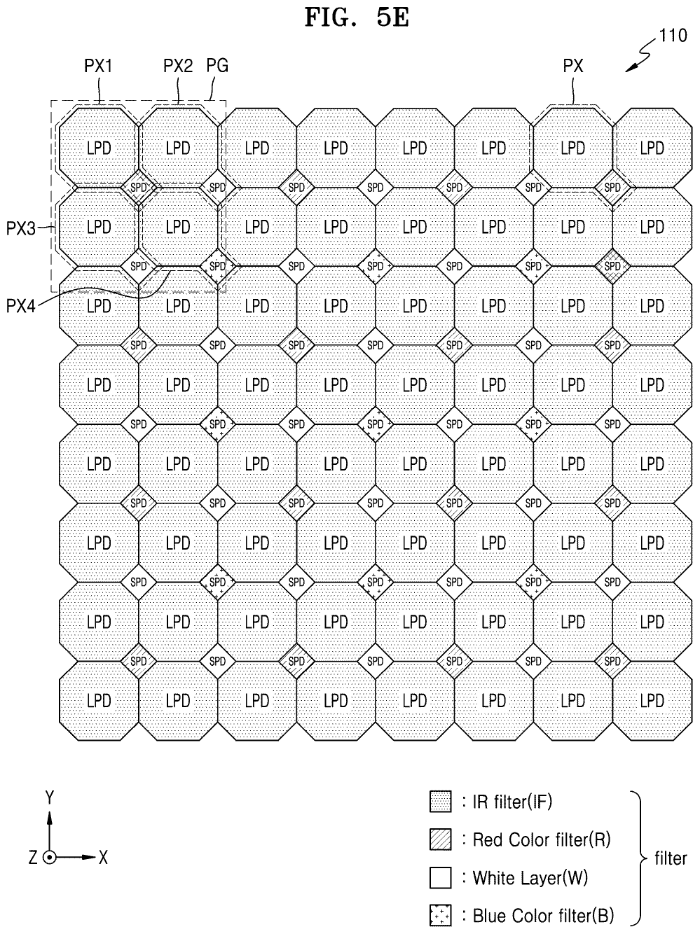

FIG. 5A is a diagram of the pixel array 110 having a Bayer pattern according to some example embodiments. Although FIG. 5A illustrates that the pixel array 110 includes 64 pixels PX, the example embodiments are not limited thereto, and the pixel array 110 may include more or fewer than 64 pixels PX. Duplicate descriptions in the descriptions given above are omitted.

Referring to FIG. 5A, a pixel group PG may include 2×2 pixels PX, and the pixel group PG may be repeatedly arranged in two dimensions in the first direction (X-axis direction) and the second direction (Y-axis direction) in the pixel array 110. FIG. 5A illustrates the pixel array 110 having a Bayer pattern. Each pixel PX of the pixel group PG may be referred to as a unit pixel.

The pixels PX included in the pixel group PG may include infrared pixels, the first photodiode LPD may detect light in the infrared ray region, and the second photodiode SPD may detect light in the visible ray region. For example, the unit pixel may include the infrared pixel comprising the first photodiode LPD and the non-infrared pixel comprising a second PD having a smaller light-receiving area than the first PD in a plan view. A color filter CF may be arranged above the second photodiode SPD of each pixel PX, and the color filter CF of each pixel PX may form a Bayer pattern.

The pixel group PG may include the first pixel PX1, the second pixel PX2, the third pixel PX3, and the fourth pixel PX4. The first pixel PX1 and the second pixel PX2 may be arranged side by side in the first direction. The first pixel PX1 and the third pixel PX3 may be arranged side by side in the second direction. The third pixel PX3 and the fourth pixel PX4 may be arranged side by side in the first direction. The first pixel PX1 may include the first color filter, the second pixel PX2 may include the second color filter, the third pixel PX3 may include the third color filter, and the fourth pixel PX4 may include the fourth color filter. In some example embodiments, the colors of the second color filter and the third color filter may be the same. The colors of the first color filter, the second color filter, and the fourth color filter may be different from each other.

For example, the first color filter may include a red color filter R, the second color filter may include a green color filter G, the third color filter may include the green color filter G, and the fourth color filter may include a blue color filter B. In the 2×2 array-type pixel group PG, the red color filter R and the blue color filter B may be respectively arranged on the second photodiodes SPD in one diagonal direction and the green color filters G may be respectively arranged on the second photodiodes SPD in the other diagonal direction. In the pixel array 110, a first row in which the red color filter R and the green color filter G are alternately arranged in the first direction and a second row in which the green color filter G and the blue color filter B are alternately arranged in the first direction may be repeatedly arranged.

Various arrangement methods of a color filter may be possible in addition to the Bayer pattern described with reference to FIG. 5A. The color filters of the pixels PX may be arranged in various ways according to the purpose and characteristics of the image sensor 100.

FIG. 5B is a cross-sectional view of the pixel array 110 of FIG. 5A taken along direction I-I′. Although a microlens is omitted in FIG. 5A for convenience of drawing, the microlens ML is illustrated in FIG. 5B. FIG. 5B illustrates the first pixel PX1 and the fourth pixel PX4 for convenience of description. Duplicate descriptions given above are omitted.

Referring to FIG. 5B, a cross-sectional view is illustrated in which the infrared filter IF and the color filter CF are respectively arranged above the first photodiode LPD and the second photodiode SPD. The plurality of pixels included in the pixel array of the inventive concepts may have a Deep Trench Isolation (DTI) structure. For example, the first photodiode LPD and the second photodiode SPD may be fully isolated by at least one isolation layer 502, 504 that contacts both of an upper and lower surfaces of the substrate (the upper surface opposing the lower surface of the substrate), or they may be partially isolated by at least one isolation layer that contacts only the lower surface of the substrate (not contact the upper surface of the substrate). Similarly, adjacent pixels may also be fully isolated by at least one isolation layer 501, 503, 505 that contacts both of the upper and lower surfaces of the substrate, or partially isolated by at least one isolation layer that contacts only the lower surface (not contact the upper surface of the substrate). In addition, the first microlens ML1 is arranged on the infrared filter IF and the second microlens ML2 is arranged on the color filter CF.

The infrared filter IF may be arranged above the first photodiode LPD, and the first microlens ML1 may be arranged on the infrared filter IF. The color filter CF may be arranged above the second photodiode SPD, and the second microlens ML2 may be arranged on the color filter CF. In the first pixel PX1, the infrared filter IF may be arranged above the first photodiode LPD and the red color filter R may be arranged above the second photodiode SPD. In the fourth pixel PX4, the infrared filter IF may be arranged above the first photodiode LPD and the blue color filter B may be arranged above the second photodiode SPD.

FIG. 5C is a diagram of the pixel array 110 including a yellow color filter Y and a cyan color filter Cy according to some example embodiments. Duplicate descriptions given with reference to FIG. 5A are omitted.

Referring to FIG. 5C, the pixel group PG may include the first pixel PX1, the second pixel PX2, the third pixel PX3, and the fourth pixel PX4. The first pixel PX1 may include the first color filter, the second pixel PX2 may include the second color filter, the third pixel PX3 may include the third color filter, and the fourth pixel PX4 may include the fourth color filter. In some example embodiments, the colors of the second color filter and the third color filter may be the same. The colors of the first color filter, the second color filter, and the fourth color filter may be different from each other.

For example, the first color filter may include the red color filter R, the second color filter may include the yellow color filter Y, the third color filter may include the yellow color filter Y, and the fourth color filter may include the cyan color filter Cy. In the 2×2 array-type pixel group PG, the red color filter R and the cyan color filter Cy may be respectively arranged on the second photodiodes SPD in one diagonal direction and the yellow color filters Y may be respectively arranged on the second photodiodes SPD in the other diagonal direction.

FIG. 5D is a diagram of the pixel array 110 including a white layer W and the green color filter G according to some example embodiments. Duplicate descriptions given with reference to FIG. 5A are omitted.

Referring to FIG. 5D, the pixel group PG may include the first pixel PX1, the second pixel PX2, the third pixel PX3, and the fourth pixel PX4. In some example embodiments, the colors of the second color filter and the third color filter may be the same. The colors of the first color filter, the second color filter, and the fourth color filter may be different from each other. In some example embodiments, Among the first color filter to the fourth color filters, at least some may be replaced with a white layer that transmits light of all spectra.

For example, the first color filter may include the red color filter R, the second color filter may include the white layer W, the third color filter may include the white layer W, and the fourth color filter may include the green color filter G. In the 2×2 array-type pixel group PG, the red color filter R and the green color filter G may be respectively arranged on the second photodiodes SPD in one diagonal direction, and the white layer W may be respectively arranged on the second photodiodes SPD in the other diagonal direction.

As another example, referring to FIG. 5A and FIG. 5D, a layer that can transmit all light of RGB may be disposed in the position where the Green color filter is located in FIG. 5A (instead of the Green color filter). In this specification, the layer that transmits light of all spectra (including red, green, and blue spectrums) is referred to as a white layer and a pixel with the white layer is referred to as a white pixel.

FIG. 5E is a diagram of the pixel array 110 including the white layer W and the blue color filter B according to some example embodiments. Compared to FIG. 5D, the fourth color filter in FIG. 5D may include the green color filter G and the fourth color filter in FIG. 5E may include the blue color filter B. Duplicate descriptions given above are omitted.

Referring to FIG. 5E, the first color filter may include the red color filter R, the second color filter may include the white layer W, the third color filter may include the white layer W, and the fourth color filter may include the blue color filter B. In the 2×2 array-type pixel group PG, the red color filter R and the blue color filter B may be respectively arranged on the second photodiodes SPD in one diagonal direction, and the white layer W may be respectively arranged on the second photodiodes SPD in the other diagonal direction.

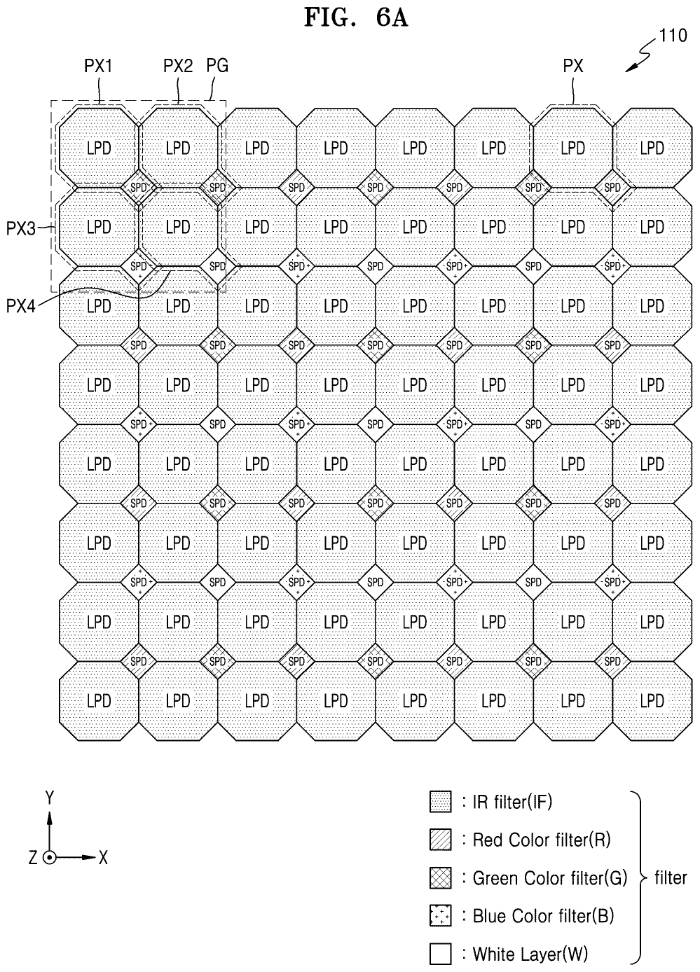

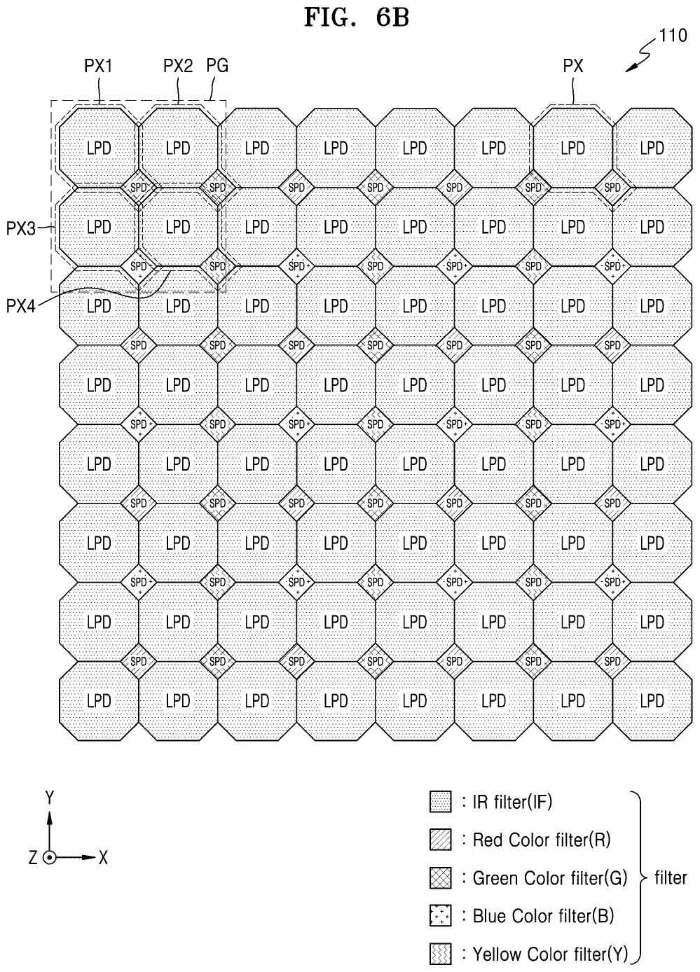

FIG. 6A is a diagram of the pixel array 110 having a red-green-blue-white (RGBW) pattern according to some example embodiments. Although FIG. 6A illustrates that the pixel array 110 includes 64 pixels PX, the example embodiments are not limited thereto, and the pixel array 110 may include more or fewer than 64 pixels PX. Duplicate descriptions given above are omitted.

Referring to FIG. 6A, the pixel group PG may include 2×2 pixels PX, and the pixel group PG may be repeatedly arranged in two dimensions in the first direction (X-axis direction) and the second direction (Y-axis direction) in the pixel array 110. The pixel group PG may include the first pixel PX1, the second pixel PX2, the third pixel PX3, and the fourth pixel PX4. Each pixel PX of the pixel group PG may be referred to as a unit pixel. For example, the unit pixel may include the infrared pixel comprising the first photodiode LPD and the non-infrared pixel comprising a second PD having a smaller light-receiving area than the first PD in a plan view. The first pixel PX1 may include the first color filter, the second pixel PX2 may include the second color filter, the third pixel PX3 may include the third color filter, and the fourth pixel PX4 may include the fourth color filter. In some example embodiments, the colors of the first color filter, the second color filter, the third color filter, and the fourth color filter may be different from each other.

For example, the first color filter may include the red color filter R, the second color filter may include the green color filter G, the third color filter may include the blue color filter B, and the fourth color filter may include the white layer W. In the 2×2 array-type pixel group PG, the red color filter R and the white layer W may be respectively arranged on the second photodiodes SPD in one diagonal direction and the green color filter G and the blue color filter B may be respectively arranged on the second photodiodes SPD in the other diagonal direction.

In the pixel array 110, the first row in which the red color filter R and the green color filter G are alternately arranged in the first direction, and the second row in which the blue color filter B and the white layer W are alternately arranged in the first direction may be repeatedly arranged. An arrangement method of the color filters may include arrangement methods according to various color filters in addition to the color filters described with reference to FIG. 6A.

FIG. 6B is a diagram of the pixel array 110 having the red-green-blue-yellow (RGBY) pattern according to some example embodiments. Compared to FIG. 6A, the fourth color filter in FIG. 6A may include the white layer W and the fourth color filter in FIG. 6B may include the yellow color filter Y. Duplicate descriptions in the descriptions given above are omitted.

Referring to FIG. 6B, the first color filter may include the red color filter R, the second color filter may include the green color filter G, the third color filter may include the blue color filter B, and the fourth color filter may include the yellow color filter Y. In the 2×2 array-type pixel group PG, the red color filter R and the yellow color filter Y may be respectively arranged on the second photodiodes SPD in one diagonal direction and the green color filter G and the blue color filter B may be respectively arranged on the second photodiodes SPD in the other diagonal direction.

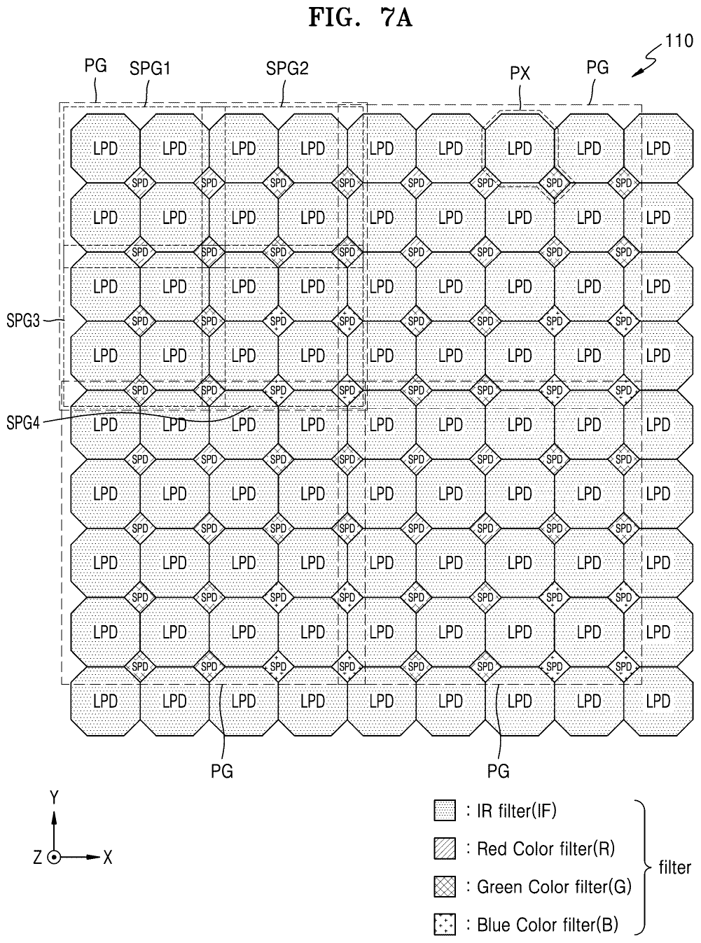

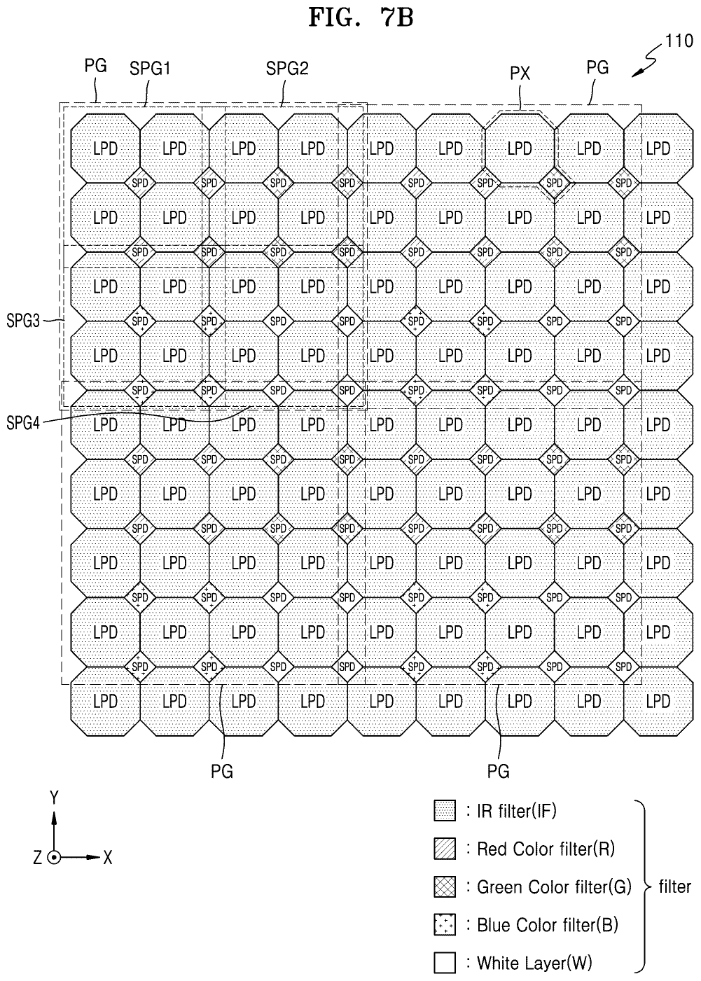

FIG. 7A is a diagram of the pixel array 110 including pixel groups according to some example embodiments. Duplicate descriptions given above are omitted.

Referring to FIG. 7A, the pixel array 110 may include a plurality of pixel groups PG each including 2n×2n (n is a positive integer of 2 or more) pixels PX. Each of the plurality of pixel groups PG may include sub-pixel groups SPG. The sub-pixel group SPG may include at least two or more pixels PX. For example, the pixel group PG may include four sub-pixel groups SPG. The pixel group PG may include a first sub-pixel group SPG1, a second sub-pixel group SPG2, a third sub-pixel group SPG3, and a fourth sub-pixel group SPG4. Each sub-pixel group SPG may include n×n pixels PX. Each pixel PX of the sub-pixel groups SPG may be referred to as a unit pixel. For example, the unit pixel may include the infrared pixel comprising the first photodiode LPD and the non-infrared pixel comprising a second PD having a smaller light-receiving area than the first PD in a plan view.

The color filters CF of the pixels PX included in one sub-pixel group SPG may have the same color. For example, the sub-pixel group SPG may include n×n pixels PX, and the color filter CF may be arranged in the second photodiode SPD of each of the n×n pixels PX. The color filters CF included in the sub-pixel group SPG may be the same. For example, n×n color filters CF included in the first sub-pixel group SPG1 may include the first color filter. n×n color filters CF included in the second sub-pixel group SPG2 may include the second color filters. n×n color filters CF included in the third sub-pixel group SPG3 may include the third color filters. n×n color filters CF included in the fourth sub-pixel group SPG4 may include the fourth color filters.

In some example embodiments, the pixel group PG may include 4×4 pixels PX, and the pixel group PG may be repeatedly arranged in two dimensions in the first direction (X-axis direction) and the second direction (Y-axis direction) in the pixel array 110. The pixel group PG may be divided into four sub-pixel groups SPG, and each sub-pixel group SPG may include 2×2 pixels PX.

The sub-pixel group SPG may be classified according to positions of the pixels PX in the pixel group PG. Four pixels PX at the upper left corner of the pixel group PG may be classified as the first sub-pixel group SPG1, four pixels PX at the upper right corner of the pixel group PG may be classified as the second sub-pixel group SPG2, four pixels PX at the lower left corner of the pixel group PG may be classified as the third sub-pixel group SPG3, and four pixels PX at the lower right corner of the pixel group PG may be classified as the fourth sub-pixel group SPG4. However, the example embodiments are not limited thereto, and for example, pixels PX on the first row (or first column) in the pixel group PG may also be classified as the first sub-pixel group SPG1, pixels PX on the second row (or second column) in the pixel group PG may also be classified as the second sub-pixel group SPG2, pixels PX on the third row (or third column) in the pixel group PG may also be classified as the third sub-pixel group SPG3, pixels PX on the fourth row (or fourth column) in the pixel group PG may also be classified as the fourth sub-pixel group SPG4.

Each of the four pixels PX included in the first sub-pixel group SPG1 may include the infrared filter IF arranged above the first photodiode LPD and the first color filter arranged above the second photodiode SPD. Similar to the first sub-pixel group SPG1, the second sub-pixel group SPG2 may include the second color filter, the third sub-pixel group SPG3 may include the third color filter, and the fourth sub-pixel group SPG4 may include the fourth color filter.

In some example embodiments, the colors of the second color filter of the second sub-pixel group SPG2 and the third color filter of the third sub-pixel group SPG3 may be the same. For example, a red color filter R may be arranged above the four second photodiodes SPD of the first sub-pixel group SPG1, a blue color filter B may be arranged above the four second photodiodes SPD of the fourth sub-pixel group SPG4, and a green color filter G may be arranged above the eight second photodiodes SPD of the second sub-pixel group SPG2 and the third sub-pixel group SPG3. The color filters CF of the pixel group PG may form a tetra pattern.

However, the example embodiments are not necessarily limited thereto, and various arrangement methods of the color filters CF in addition to the Bayer pattern described with reference to FIG. 7A may be possible. For example, the red color filters R may be arranged above the second photodiode SPDs of the first sub-pixel group SPG1, the cyan color filters Cy may be arranged above the second photodiodes SPD of the fourth sub-pixel group SPG4, and the yellow color filters Y may be arranged above the second photodiodes SPD of the second sub-pixel group SPG2 and the third sub-pixel group SPG3.

As another example, the red color filters R may be arranged above the second photodiode SPDs of the first sub-pixel group SPG1, the green color filters G may be arranged above the second photodiodes SPD of the fourth sub-pixel group SPG4, and the white layer W may be arranged above the second photodiodes SPD of the second sub-pixel group SPG2 and the third sub-pixel group SPG3. As another example, the red color filters R may be arranged above the second photodiode SPDs of the first sub-pixel group SPG1, the blue color filters B may be arranged above the second photodiodes SPD of the fourth sub-pixel group SPG4, and the white layer W may be arranged above the second photodiodes SPD of the second sub-pixel group SPG2 and the third sub-pixel group SPG3.

FIG. 7B is a diagram of the pixel array 110 including pixel groups PG according to some example embodiments. Duplicate descriptions given with reference to FIG. 7A are omitted.

In some example embodiments, the colors of the first color filter of the first sub-pixel group SPG1, the second color filter of the second sub-pixel group SPG2, the third color filter of the third sub-pixel group SPG3, and the fourth color filter of the fourth sub-pixel group SPG4 may be different from each other. For example, four red color filters R may be arranged above four second photodiodes SPD of the first sub-pixel group SPG1, four green color filters G may be arranged above four second photodiodes SPD of the second sub-pixel group SPG2, four blue color filters B may be arranged above four second photodiodes SPD of the third sub-pixel group SPG3, and four white layer W may be arranged above four second photodiodes SPD of the fourth sub-pixel group SPG4.

However, the example embodiments are not necessarily limited thereto, and various arrangement methods of the color filters CF in addition to the pattern described with reference to FIG. 7B may be possible. For example, four red color filters R may be arranged above four second photodiodes SPD of the first sub-pixel group SPG1, four green color filters G may be arranged above four second photodiodes SPD of the second sub-pixel group SPG2, four blue color filters B may be arranged above four second photodiodes SPD of the third sub-pixel group SPG3, and four yellow color filter Y may be arranged above four second photodiodes SPD of the fourth sub-pixel group SPG4.

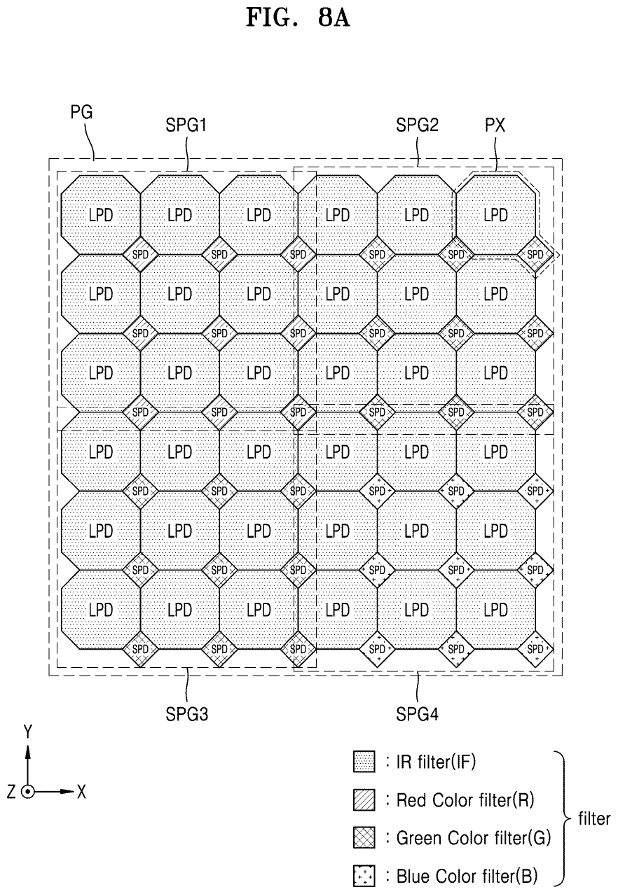

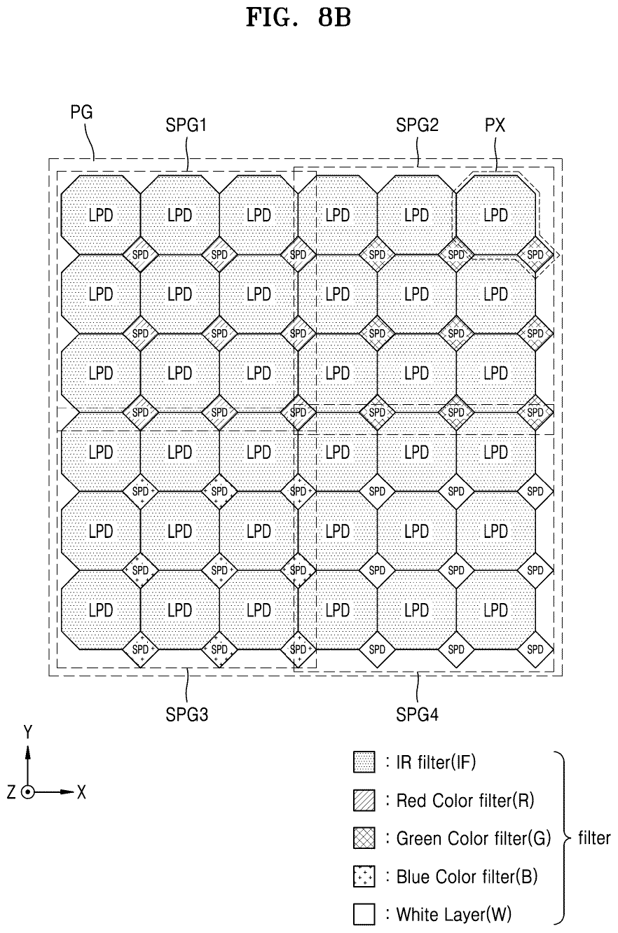

FIG. 8A is a diagram of the pixel group PG including 6×6 pixels according to some example embodiments. Duplicate descriptions given above are omitted.

Referring to FIG. 8A, the pixel group PG may include 6×6 pixels PX, and the pixel group PG may be repeatedly arranged in two dimensions in the first direction (X-axis direction) and the second direction (Y-axis direction) in a pixel array (for example, the pixel array 110 of FIG. 1). The pixel group PG may be divided into four sub-pixel groups SPG, and each sub-pixel group SPG may include 3×3 pixels PX. Each pixel PX of the sub-pixel groups SPG may be referred to as a unit pixel. For example, the unit pixel may include the infrared pixel comprising the first photodiode LPD and the non-infrared pixel comprising a second PD having a smaller light-receiving area than the first PD in a plan view.

In some example embodiments, the colors of the second color filter of the second sub-pixel group SPG2 and the third color filter of the third sub-pixel group SPG3 may be the same. For example, nine red color filters R may be arranged above nine second photodiodes SPD of the first sub-pixel group SPG1, nine blue color filters B may be arranged above nine second photodiodes SPD of the fourth sub-pixel group SPG4, and eighteen green color filters G may be arranged above the eighteen second photodiodes SPD of the second sub-pixel group SPG2 and the third sub-pixel group SPG3. For example, the color filters CF of the pixel group PG may form a nona pattern. However, the example embodiments are not necessarily limited thereto, and various arrangement methods of the color filters CF in addition to the pattern described with reference to FIG. 8A may be possible.

FIG. 8B is a diagram of the pixel group PG including 6×6 pixels PX according to some example embodiments. Duplicate descriptions given with reference to FIG. 8A are omitted.

Referring to FIG. 8B, the colors of the first color filter of the first sub-pixel group SPG1, the second color filter of the second sub-pixel group SPG2, the third color filter of the third sub-pixel group SPG3, and the fourth color filter of the fourth sub-pixel group SPG4 may be different from each other. For example, nine red color filters R may be arranged above nine second photodiodes SPD of the first sub-pixel group SPG1, nine green color filters G may be arranged above nine second photodiodes SPD of the second sub-pixel group SPG2, nine blue color filters B may be arranged above nine second photodiodes SPD of the third sub-pixel group SPG3, and nine white layer W may be arranged above nine second photodiodes SPD of the fourth sub-pixel group SPG4. However, the example embodiments are not necessarily limited thereto, and various arrangement methods of the color filters CF in addition to the pattern described with reference to FIG. 8B may be possible.

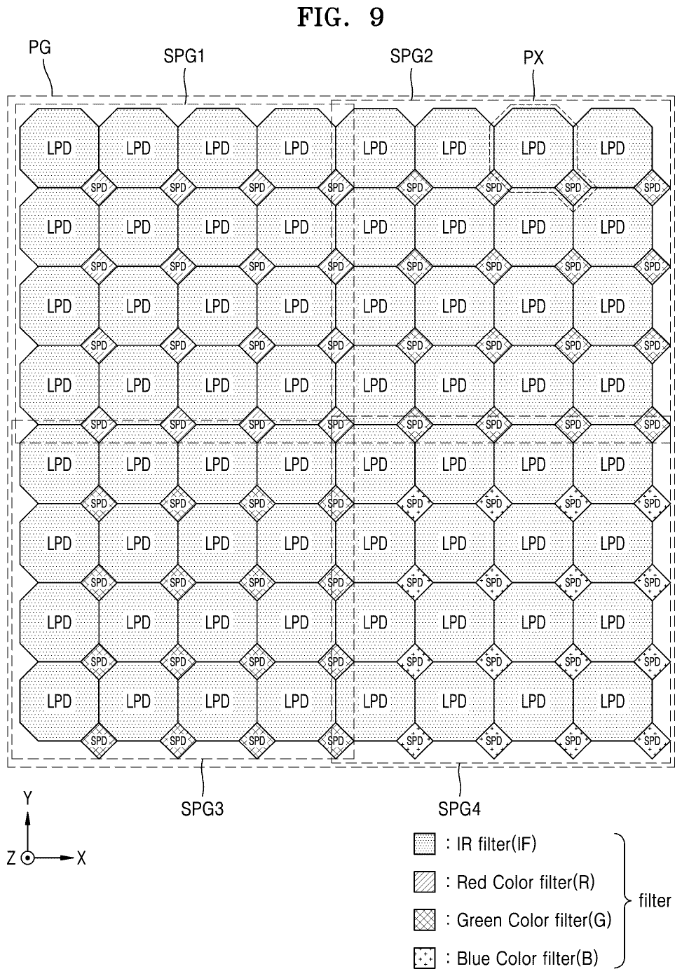

FIG. 9 is a diagram of the pixel group PG including 8×8 pixels according to some example embodiments. Duplicate descriptions given above are omitted.

Referring to FIG. 9, the pixel group PG may include 8×8 pixels PX, and the pixel group PG may be repeatedly arranged in two dimensions in the first direction (X-axis direction) and the second direction (Y-axis direction) in a pixel array (for example, the pixel array 110 of FIG. 1). The pixel group PG may be divided into four sub-pixel groups SPG, and each sub-pixel group SPG may include 4×4 pixels PX.

In some example embodiments, the colors of the second color filter of the second sub-pixel group SPG2 and the third color filter of the third sub-pixel group SPG3 may be the same. For example, sixteen red color filters R may be arranged above sixteen second photodiodes SPD of the first sub-pixel group SPG1, sixteen blue color filters B may be arranged above sixteen second photodiodes SPD of the fourth sub-pixel group SPG4, and thirty two green color filters G may be arranged above the thirty two second photodiodes SPD of the second sub-pixel group SPG2 and the third sub-pixel group SPG3. For example, the color filters CF of the pixel group PG may form a hexadeca pattern.

In some example embodiments, the colors of the first color filter of the first sub-pixel group SPG1, the second color filter of the second sub-pixel group SPG2, the third color filter of the third sub-pixel group SPG3, and the fourth color filter of the fourth sub-pixel group SPG4 may also be different from each other. For example, the red color filters R may be arranged above the second photodiodes SPD of the first sub-pixel group SPG1, the green color filters G may be arranged above the second photodiodes SPD of the second sub-pixel group SPG2, the blue color filters B may be arranged above the second photodiodes SPD of the third sub-pixel group SPG3, and the white layer W may be arranged above the second photodiodes SPD of the fourth sub-pixel group SPG4. However, the example embodiments are not necessarily limited thereto, and various arrangement methods of the color filters CF in addition to the pattern described with reference to FIG. 9 may be possible.

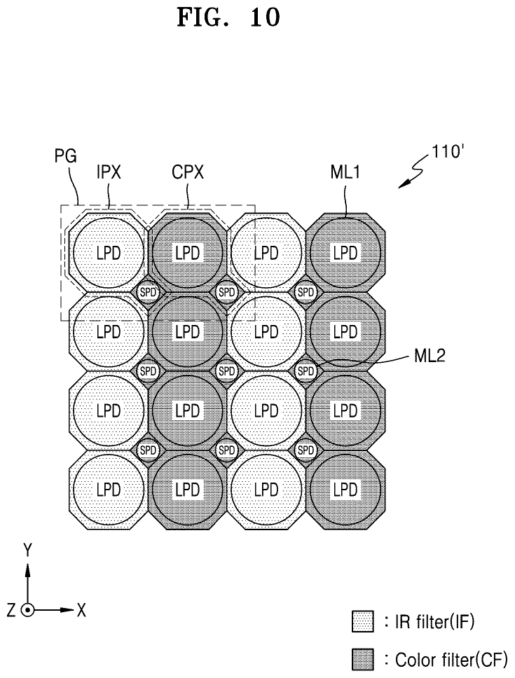

FIG. 10 is a diagram of a pixel array 110′ including an IR pixel IPX and a color pixel CPX according to some example embodiments. Compared with FIG. 3, the pixel array 110 of FIG. 3 may include only the IR pixel, and the pixel array 110′ of FIG. 10 may include the IR pixel IPX and the color pixel CPX. Duplicate descriptions given above are omitted.

Referring to FIG. 10, the pixel array 110′ may include the plurality of pixels PX. The pixel array 110′ may include the infrared pixel IPX and the color pixel CPX. The pixel group PG may include the IR pixel IPX and the color pixel CPX, and the pixel group PG may be repeatedly arranged in the pixel array 110′ in the first direction and the second direction. The IR pixel IPX and the color pixel CPX may be arranged in the pixel array 110′ in a particular pattern. Although FIG. 10 illustrates that the pixel group PG includes one IR pixel IPX and one color pixel CPX, the example embodiments are not limited thereto, and the pixel group PG may include at least one IR pixel IPX and at least one color pixel CPX.

Each of the IR pixel IPX and the color pixel CPX may include the first photodiode LPD and the second photodiode SPD. The IR pixel IPX may include the first filter arranged above the first photodiode LPD of the IR pixel IPX and the second filter arranged above the second photodiode SPD of the IR pixel IPX. The first filter may include the IR filter IF which absorbs light in the infrared ray region. The second filter may include the color filter CF which absorbs light in the visible ray region. The IR pixel may mean a pixel PX in which the IR filter IF is arranged above the first photodiode LPD.

The color pixel CPX may include the third filter arranged above the first photodiode LPD of the color pixel CPX and the fourth filter arranged above the second photodiode SPD. The third filter may include the color filter CF which absorbs light in the visible ray region. The fourth filter may include a filter which absorbs light in the infrared ray region and light in the visible ray region. The fourth filter may be one of the color filter CF and the IR filter IF. The color pixel CPX may mean a pixel PX in which the color filter CF is arranged above the first photodiode LPD. The color filter CF or the IR filter IF may be arranged above the second photodiode SPD of the color pixel CPX.

In some example embodiments, when the fourth filter of the color pixel CPX is the color filter CF, the third filter and the fourth filter of the color pixel CPX may be the same color filters CF. The color filters CF of the same color may be arranged above the first photodiode LPD and the second photodiode SPD of the color pixel CPX. For example, the green color filter G may be arranged above the first photodiode LPD and the second photodiode SPD of the color pixel CPX. Although FIG. 10 illustrates that the color filter CF is arranged above the second photodiode SPD of the color pixel CPX, the example embodiments are not limited thereto, and the IR filter IF may be arranged above the second photodiode SPD of the color pixel CPX. The pixel groups PG may be repeatedly arranged in two dimensions in the first direction (X-axis direction) and the second direction (Y-axis direction) in the pixel array 110′, and the pixel group PG may include at least one color pixel CPX and at least one IR pixel IPX. For example, as illustrated in FIG. 10, the IR pixels IPX and the color pixels CPX may be alternately arranged in an array in the pixel array 110′. However, the example embodiments are not necessarily limited thereto, and the IR pixels IPX and the color pixels CPX may form a particular pattern and may be variously arranged in the pixel array 110′. In addition, the color filters CF included in the IR pixels IPX and the color pixels CPX may transmit various colors and may be arranged in various ways.

In the image sensor 100 according to the inventive concepts, the pixel group PG including the IR pixel IPX and the color pixel CPX may be repeatedly arranged in the pixel array 110′. Because the IR filter IF and the color filter CF are uniformly arranged in the entire area of the pixel array 110′, the photoelectric conversion efficiency may be improved even in the edge area of the pixel array 110′, and at the same time, the high dynamic range may be improved. Accordingly, the quality of an image may be improved.

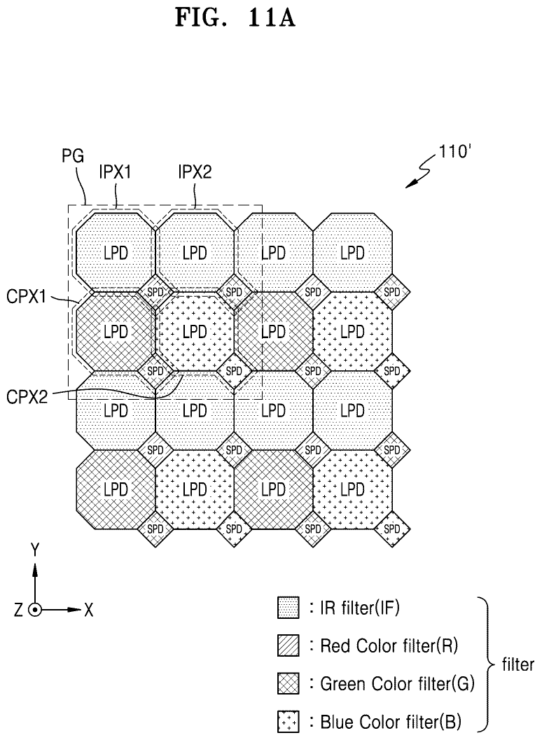

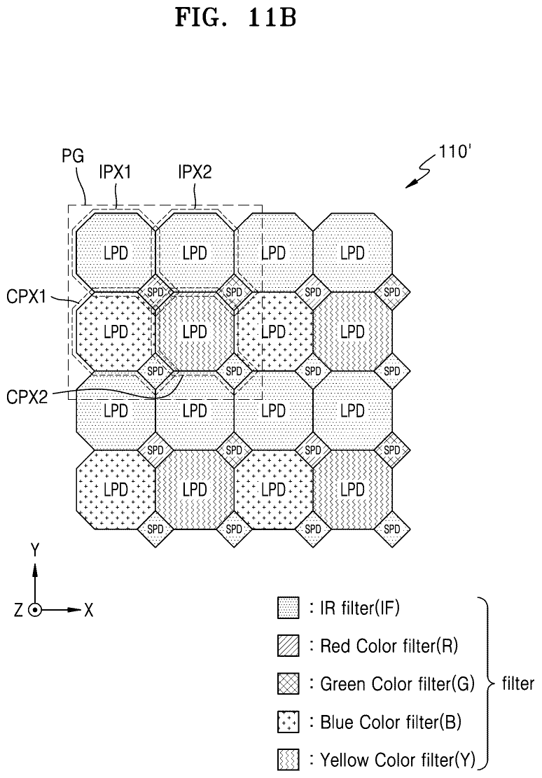

FIG. 11A is a diagram of the pixel group PG including the IR pixel IPX and the color pixel CPX according to some example embodiments. For convenience of explanation, the illustration of the microlens is omitted in in FIG. 11A. Duplicate descriptions given above are omitted.

In the pixel array 110′, the pixel groups PG may be repeatedly arranged in the first direction (x-axis direction) and the second direction (Y-axis direction). Each of the pixel groups PG may include at least one IR pixel IPX and at least one color pixel CPX. In some example embodiments, the pixel group PG may include a first IR pixel IPX1, a second IR pixel IPX2, a first color pixel CPX1, and a second color pixel CPX2. The first IR pixel IPX1 and the second IR pixel IPX2 may be arranged side by side in the first direction, the first color pixel CPX1 and the second color pixel CPX2 may be arranged side by side in the first direction, the first IR pixel IPX1 and the first color pixel CPX1 may be arranged side by side in the second direction, and the second IR pixel IPX2 and the second color pixel CPX2 may be arranged in the second direction.

For example, the color filter CF may be arranged above the second photodiode SPD of the color pixel CPX. The fourth filter of the color pixel CPX may include the color filter CF. The color filters CF included in the pixel group PG may be arranged in various ways. The pixel group PG may include color filters CF which are the second filter of the first IR pixel IPX1, the second filter of the second IR pixel IPX2, the third filter and the fourth filter of the first color pixel CPX1, the third filter and the fourth filter of the second color pixel CPX2. However, the example embodiments are not necessarily limited thereto, and the IR filter IF may be arranged above the second photodiode SPD of the color pixel CPX. The fourth filter of the color pixel CPX may also include the IR filter IF.

The second filter of the first IR pixel IPX1 may include the first color filter, the second filter of the second IR pixel IPX2 may include the second color filter, the third filter and the fourth filter of the first color pixel CPX1 may include the third color filter, and the third filter and the fourth filter of the second color pixel CPX2 may include the fourth color filters.

In some example embodiments, the colors of the second color filter and the third color filter may be the same. The colors of the first color filter, the second color filter, and the fourth color filter may be different from each other. For example, the first color filter may include the red color filter R, the second color filter may include the green color filter G, the third color filter may include the green color filter G, and the fourth color filter may include the blue color filter B. The red color filter R may be arranged on the second photodiode SPD of the first IR pixel IPX1, the green color filter G may be arranged above the second photodiode SPD of the second IR pixel IPX2, the green color filter G may be arranged above the first photodiode LPD and the second photodiode SPD of the first color pixel CPX1, and the blue color filters B may be arranged above the first photodiode LPD and the second photodiode SPD of the second color pixel CPX2. The color filter CF of each pixel PX included in the pixel group PG may form a Bayer pattern.

However, the example embodiments are not necessarily limited thereto, and various arrangement methods of the color filters CF in addition to the Bayer pattern described with reference to FIG. 11A may be possible. The color filters CF of the IR pixels IPX and the color pixels CPX may be arranged in various ways according to the use and characteristics of the image sensor 100.

FIG. 11B is a diagram illustrating the pixel group PG including the IR pixel IPX and the color pixel CPX according to some example embodiments. FIG. 11B illustrates a case in which the second photodiode SPD of the color pixel CPX senses light in an infrared ray region. Duplicate descriptions given with reference to FIG. 11A are omitted.

Referring to FIG. 11B, the IR filter IF may be arranged above the second photodiode SPD of the color pixel CPX. The fourth filter of the color pixel CPX may include the IR filter IF. The color filters CF included in the pixel group PG may be arranged in various ways. The pixel group PG may include color filters CF which are the second filter of the first IR pixel IPX1, the second filter of the second IR pixel IPX2, the third filter of the first color pixel CPX1, and the third filter of the second color pixel CPX2. However, the example embodiments are not necessarily limited thereto, and the color filter CF may be arranged above the second photodiode SPD of the color pixel CPX.

The second filter of the first IR pixel IPX1 may include the first color filter, the second filter of the second IR pixel IPX2 may include the second color filter, the third filter of the first color pixel CPX1 may include the third color filter, and the fourth color filter of the second color pixel CPX2 may include the fourth color filter. In some example embodiments, the colors of the first color filter, the second color filter, the third color filter, and the fourth color filter may be different from each other. For example, the first color filter may include the red color filter R, the second color filter may include the green color filter G, the third color filter may include the blue color filter B, and the fourth color filter may include the yellow color filter Y.

The red color filter R may be arranged above the second photodiode SPD of the first IR pixel IPX1, the green color filter G may be arranged above the second photodiode SPD of the second IR pixel IPX2, the blue color filter B may be arranged above the first photodiode LPD of the first color pixel CPX1, and the yellow color filter Y may be arranged above the first photodiode LPD of the second color pixel CPX2. However, the example embodiments are not necessarily limited thereto, and various arrangement methods of the color filters CF may be possible.

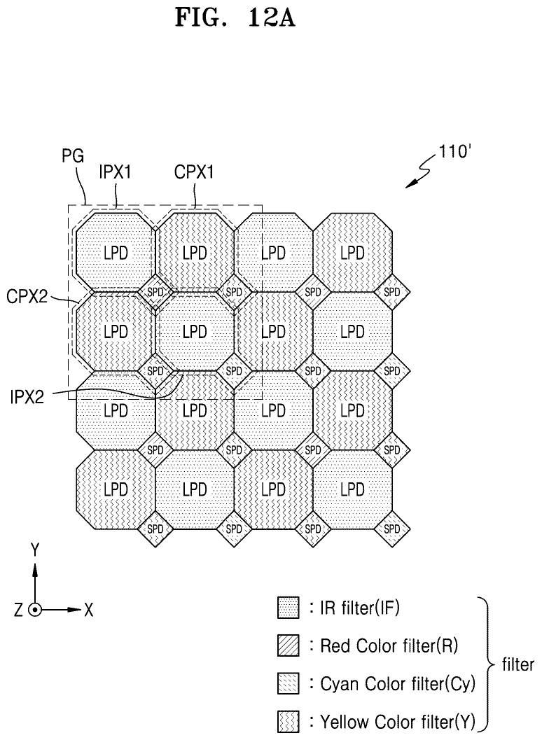

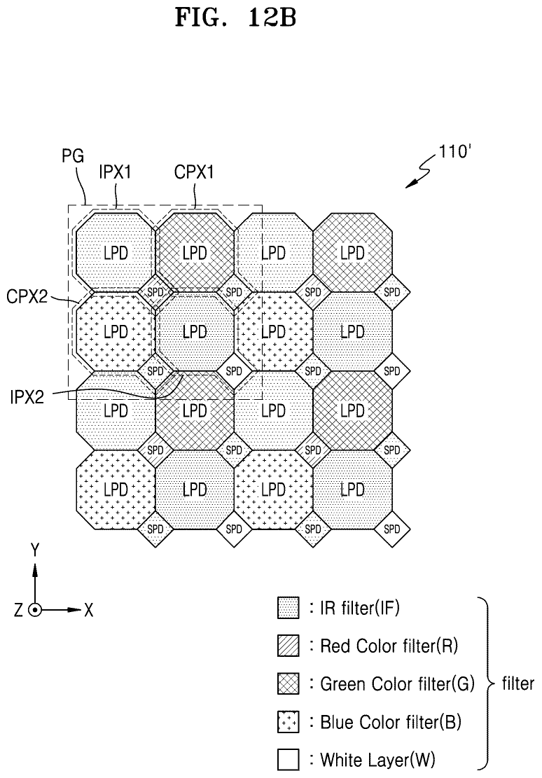

FIG. 12A is a diagram of a pattern, in which the IR pixels IPX are diagonally arranged, according to some example embodiments.

In the pixel array 110′, the pixel groups PG may be repeatedly arranged in the first direction (x-axis direction) and the second direction (Y-axis direction). In some example embodiments, the pixel group PG may include the first IR pixel IPX1, the second IR pixel IPX2, the first color pixel CPX1, and the second color pixel CPX2. The first IR pixel IPX1 and the first color pixel CPX1 may be arranged side by side in the first direction (X-axis direction), the first IR pixel IPX1 and the second color pixel CPX2 may be arranged side by side in the second direction (Y-axis direction), and the second IR pixel IPX2 and the second color pixel CPX2 may be arranged in the first direction. In the pixel group PG, the first IR pixel IPX1 and the second IR pixel IPX2 may be arranged in one diagonal direction, and the first color pixel CPX1 and the second color pixel CPX2 may be arranged in the other diagonal direction.

For example, the color filter CF may be arranged above the second photodiode SPD of the color pixel CPX. The fourth filter of the color pixel CPX may include the color filter CF. However, the example embodiments are not necessarily limited thereto, and the IR filter IF may be arranged above the second photodiode SPD of the color pixel CPX.

For example, the red color filter R may be arranged above the second photodiode SPD of the first IR pixel IPX1, the yellow color filter Y may be arranged above the first photodiode LPD and the second photodiode SPD of the first color pixel CPX1, the yellow color filter Y may be arranged above the first photodiode LPD and the second photodiode SPD of the second color pixel CPX2, and the cyan color filter Cy may be arranged above the second photodiode SPD of the second IR pixel IPX2. In the pixel group PG, the red color filter R and the cyan color filter Cy may be respectively arranged on the second photodiodes SPD in one diagonal direction, and the yellow color filters Y may be respectively arranged on the first photodiodes LPD and the second photodiodes SPD in the other diagonal direction. However, the example embodiments are not necessarily limited thereto, and various arrangement methods of the color filters CF may be possible.

FIG. 12B is a diagram of a pattern, in which the IR pixels IPX are diagonally arranged, according to some example embodiments. FIG. 12B illustrates a case in which the second photodiode SPD of the color pixel CPX senses light in the infrared ray region. Duplicate descriptions given with reference to FIG. 12A are omitted.

Referring to FIG. 12B, the IR filter IF may be arranged above the second photodiode SPD of the color pixel CPX. The fourth filter of the color pixel CPX may include the IR filter IF. However, the example embodiments are not necessarily limited thereto, and the color filter CF may also be arranged above the second photodiode SPD of the color pixel CPX.

The second filter of the first IR pixel IPX1 may include the first color filter, the third filter of the first color pixel CPX1 may include the second color filter, the third filter of the second color pixel CPX2 may include the third color filter, and the second color filter of the second IR pixel IPX2 may include the fourth color filter. In some example embodiments, the colors of the first color filter, the second color filter, the third color filter, and the fourth color filter may be different from each other. For example, the red color filter R may be arranged above the second photodiode SPD of the first IR pixel IPX1, the green color filter G may be arranged above the first photodiode LPD of the first color pixel CPX1, the blue color filter B may be arranged above the first photodiode LPD of the second color pixel CPX2, and the white layer W may be arranged above the second photodiode SPD of the second IR pixel IPX2. However, the example embodiments are not limited thereto.

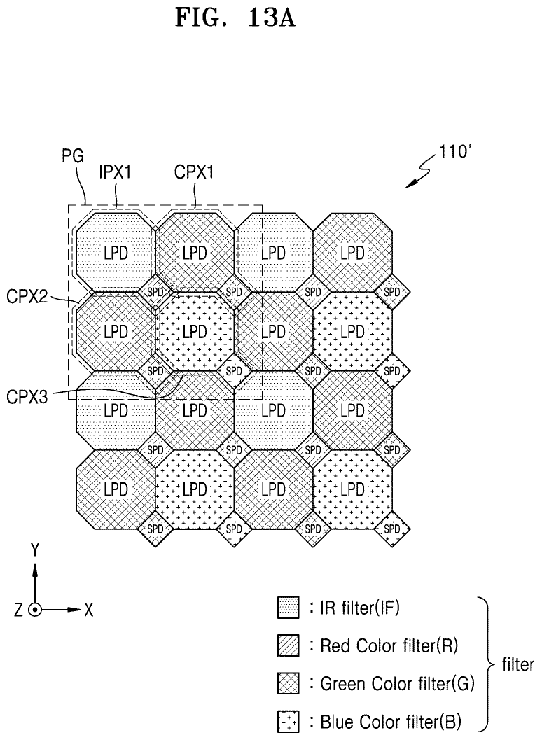

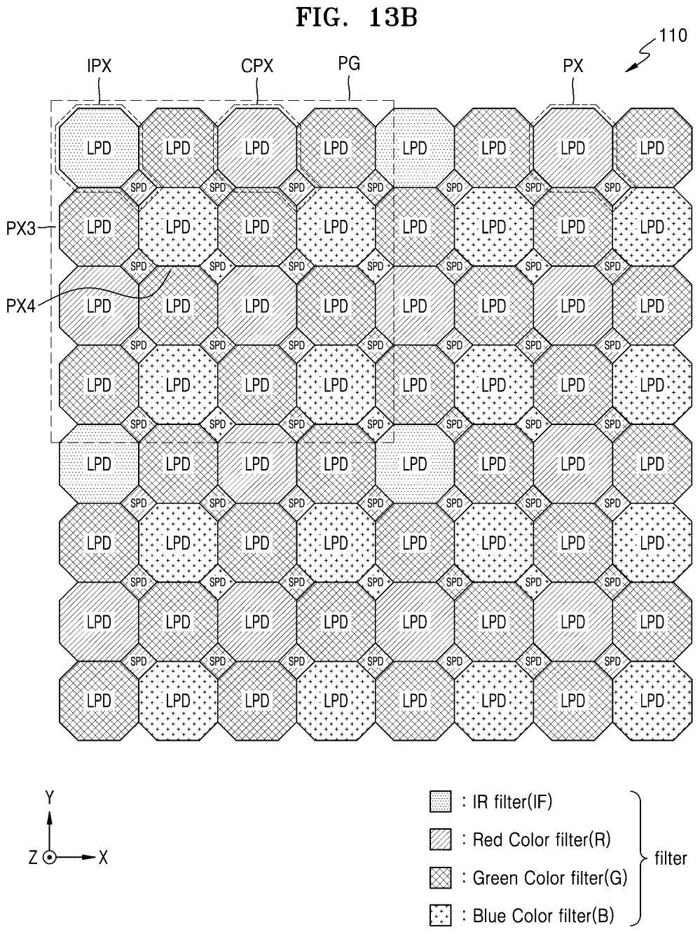

FIG. 13A is a diagram illustrating that the IR pixels IPX are included in the pixel group PG, according to some example embodiments.

Referring to FIG. 13A, the pixel array 110′ may include the pixel groups PG, and the pixel groups PG may be repeatedly arranged in the pixel array 110′ in the first direction and the second direction. Each of the pixel groups PG may include n×n pixels (n is a positive integer of 2 or more). In some example embodiments, one pixel PX of the n×n pixels PX may include the IR pixel IPX, and the remaining pixels PX of the n×n pixels PX may include the color pixels CPX.

In some example embodiments, the pixel group PG may include 2×2 pixels PX, one pixel PX of the 2×2 pixels PX may include the IR pixel IPX, and the remaining pixels PX may include the color pixels CPX. The pixel group PG may include the first IR pixel IPX1, the first color pixel CPX1, the second color pixel CPX2, and a third color pixel CPX3.

The second filter of the first IR pixel IPX1 may include the first color filter, the third filter and the fourth filter of the first color pixel CPX1 may include the second color filter, the third filter and the fourth filter of the second color pixel CPX2 may each include the third color filter, and the third filter and the fourth filter of the third color pixel CPX3 may each include the fourth color filter. In some example embodiments, the colors of the second color filter of the first color pixel CPX1 and the third color filter of the second color pixel CPX2 may be the same. For example, the first color filter may include the red color filter R, the second color filter and the third color filter may include the green color filter G, and the fourth color filter may include the blue color filter B. However, the example embodiments are not necessarily limited thereto, and various arrangement methods of the color filters CF in addition to the pattern described with reference to FIG. 13A may be possible. In a structure, in which one IR pixel IPX is included in the pixel group PG, the color filters CF may be variously arranged.

In addition, unlike as illustrated in FIG. 13A, the first color filter of the first IR pixel IPX1, the second color filter of the first color pixel CPX1, the third color filter of the second color pixel CPX2, and the fourth color filter of the third color pixel CPX3 may also be different color filters from each other. For example, the first color filter may include the red color filter R, the second color filter may include the green color filter G, the third color filter may include the blue color filter B, and the fourth color filter may include the white layer W. However, the example embodiments are not limited thereto.

FIG. 13B is a diagram of the pixel group PG including 4×4 pixels PX according to some example embodiments.

Referring to FIG. 13B, the pixel group PG may include 4×4 pixels PX, and the pixel groups PG may be repeatedly arranged in the pixel array 110′ in the first direction and the second direction. One pixel PX of the 4×4 pixels PX included in the pixel group PG may include the IR pixel IPX, and the remaining pixels PX may include color pixels CPX. The pixel group PG may include one IR pixel IPX and 15 color pixels CPX.

The color filters may be variously arranged in the pixel group PG. For example, in the pixel group PG, the red color filter R, the green color filter G, and the blue color filter B may form a Bayer pattern and may be repeatedly arranged. However, the example embodiments are not necessarily limited thereto, and various arrangement methods of the color filters CF may be possible. In a structure, in which one IR pixel IPX is included in the pixel group PG, the color filters CF may be variously arranged.

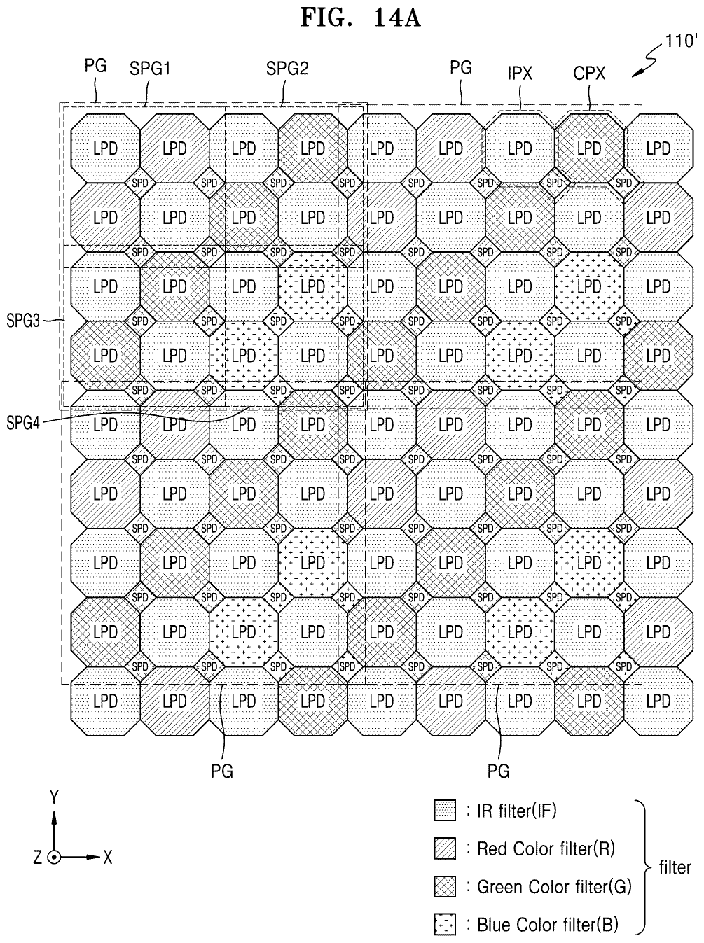

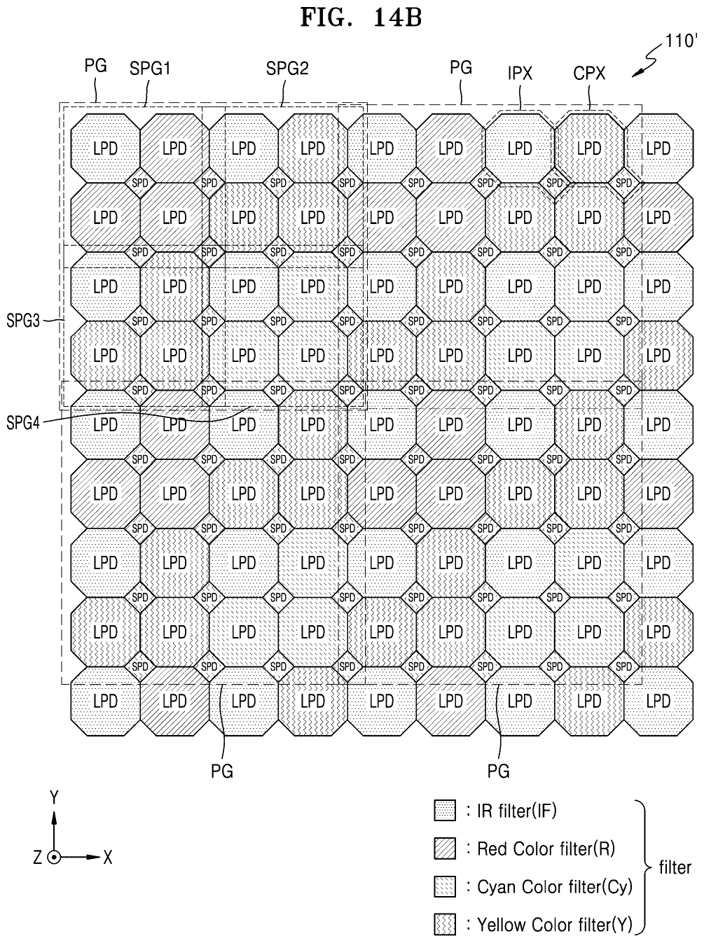

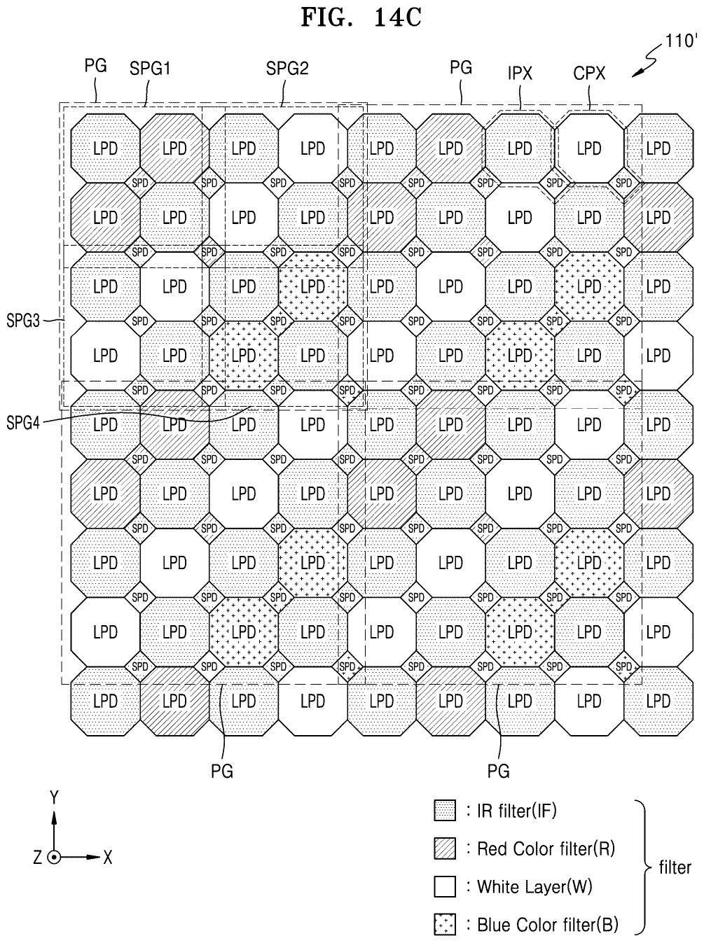

FIG. 14A is a diagram of the pixel array 110′ including pixel groups PG according to some example embodiments. Duplicate descriptions given above are omitted.

Referring to FIG. 14A, the pixel array 110′ may include the plurality of pixel groups PG each including 2n×2n (n is a positive integer of 2 or more) pixels PX. Each of the plurality of pixel groups PG may include at least one IR pixel IPX and at least one color pixel CPX. Each of the plurality of pixel groups PG may include sub-pixel groups SPG. For example, the pixel group PG may include four sub-pixel groups SPG. The pixel group PG may include the first sub-pixel group SPG1, the second sub-pixel group SPG2, the third sub-pixel group SPG3, and the fourth sub-pixel group SPG4. Each sub-pixel group SPG may include n×n pixels PX.

Each of the plurality of pixel groups PG may include at least one IR pixel IPX and at least one color pixel CPX. For example, the first sub-pixel group SPG1 may include one IR pixel IPX and three color pixels CPX, and each of the second sub-pixel group SPG2, the third sub-pixel group SPG3, and the fourth sub-pixel group SPG4 may include four color pixels CPX. However, the example embodiments are only an example, and the number of the IR pixels IPX and the color pixels CPX included in the sub-pixel group SPG is not necessarily limited thereto.

In some example embodiments, each of the first sub-pixel group SPG1, the second sub-pixel group SPG2, the third sub-pixel group SPG3, and the fourth sub-pixel group SPG4 may include at least one IR pixel IPX and at least one color pixel CPX. For example, each of the first sub-pixel group SPG1, the second sub-pixel group SPG2, the third sub-pixel group SPG3, and the fourth sub-pixel group SPG4 may include at least two IR pixels IPX and at least two color pixels CPX. However, the example embodiments are only an example, and the number of the IR pixels IPX and the color pixels CPX included in the sub-pixel group SPG is not necessarily limited thereto.

The color filters CF of the pixels PX included in one sub-pixel group SPG may have the same color. For example, the sub-pixel group SPG may include n×n pixels PX, and the color filters CF included in the sub-pixel group SPG may include the same color filters CF. The second filter and the third filter included in the sub-pixel group SPG may include the same color filter for each sub-pixel group SPG. For example, the color filters CF arranged above the second photodiode SPD of the IR pixel IPX and the first photodiode LPD of the color pixel CPX included in the first sub-pixel group SPG1 may include the first color filters. The color filters CF arranged above the second photodiode SPD of the IR pixel IPX and the first photodiode LPD of the color pixel CPX included in the second sub-pixel group SPG2 may include the second color filters. The color filters CF arranged above the second photodiode SPD of the IR pixel IPX and the first photodiode LPD of the color pixel CPX included in the third sub-pixel group SPG3 may include the third color filters. The color filters CF arranged above the second photodiode SPD of the IR pixel IPX and the first photodiode LPD of the color pixel CPX included in the fourth sub-pixel group SPG4 may include the fourth color filters.

In some example embodiments, the pixel group PG may include 4×4 pixels PX, and the pixel group PG may be repeatedly arranged in two dimensions in the first direction (X-axis direction) and the second direction (Y-axis direction) in the pixel array 110′. The pixel group PG may be divided into four sub-pixel groups SPG, and each sub-pixel group SPG may include 2×2 pixels PX. For example, each sub-pixel group SPG may include two IR pixels IPX and two color pixels CPX. In the sub-pixel group SPG, two IR pixels IPX may be arranged in one diagonal direction, and two color pixels CPX may be arranged in the other diagonal direction. However, the example embodiments are not necessarily limited thereto, and the number of the IR pixels IPX and the color pixels CPX included in each sub-pixel group SPG, and a method of arranging at least one of the IR pixels IPX and the color pixels CPX in the sub-pixel group SPG may vary. In some example embodiments, the pixel group PG may include various forms of 2n×2n pixels PX, such as 6×6 pixels PX and 8×8 pixels PX.

The sub-pixel group SPG may be classified according to positions of the pixels PX in the pixel group PG. Four pixels PX at the upper left corner of the pixel group PG may be classified as the first sub-pixel group SPG1, four pixels PX at the upper right corner of the pixel group PG may be classified as the second sub-pixel group SPG2, four pixels PX at the lower left corner of the pixel group PG may be classified as the third sub-pixel group SPG3, and four pixels PX at the lower right corner of the pixel group PG may be classified as the fourth sub-pixel group SPG4. However, the example embodiments are not limited thereto, and for example, pixels PX on the first row (or first column) in the pixel group PG may also be classified as the first sub-pixel group SPG1, pixels PX on the second row (or second column) in the pixel group PG may also be classified as the second sub-pixel group SPG2, pixels PX on the third row (or third column) in the pixel group PG may also be classified as the third sub-pixel group SPG3, pixels PX on the fourth row (or fourth column) in the pixel group PG may also be classified as the fourth sub-pixel group SPG4.

The second filter of the IR pixel IPX, the third filter and the fourth filter of the color pixel CPX included in the first sub-pixel group SPG1 may include the first color filter. The second filter of the IR pixel IPX, the third filter and the fourth filter of the color pixel CPX included in the second sub-pixel group SPG2 may include the second color filter. The second filter of the IR pixel IPX, the third filter and the fourth filter of the color pixel CPX included in the third sub-pixel group SPG3 may include the third color filter. The second filter of the IR pixel IPX, the third filter and the fourth filter of the color pixel CPX included in the fourth sub-pixel group SPG4 may include the fourth color filter. Although FIG. 14A illustrates that the fourth filter of the color pixel CPX includes the color filter CF, the example embodiments are not necessarily limited thereto, and the fourth filter may also include the IR filter IF.

In some example embodiments, the colors of the second color filter of the second sub-pixel group SPG2 and the third color filter of the third sub-pixel group SPG3 may be the same. For example, the first color filter of the first sub-pixel group SPG1 may include the red color filter R, the fourth color filter of the fourth sub-pixel group SPG4 may include the blue color filter B, and the second color filter and the third color filter of the second sub-pixel group SPG2 and the third sub-pixel group SPG3 may include the green color filters G. However, the example embodiments are not necessarily limited thereto, and various arrangement methods of the color filters CF in addition to the pattern described with reference to FIG. 14A may be possible.

FIG. 14B is a diagram of the pixel array 110′ including the yellow color filter Y according to some example embodiments. Duplicate descriptions given above are omitted.

In some example embodiments, each of the first sub-pixel group SPG1, the second sub-pixel group SPG2, the third sub-pixel group SPG3, and the fourth sub-pixel group SPG4 may include at least one IR pixel IPX and at least one color pixel CPX. For example, each of the first sub-pixel group SPG1, the second sub-pixel group SPG2, the third sub-pixel group SPG3, and the fourth sub-pixel group SPG4 may include one IR pixel IPX and three color pixels CPX. However, the example embodiments are only an example, and the number of the IR pixels IPX and the color pixels CPX included in the sub-pixel group SPG is not necessarily limited thereto.

The color filters CF of pixels PX included in one sub-pixel group SPG may have the same color. For example, each sub-pixel group SPG may include one IR pixel IPX and three color pixels CPX. In the sub-pixel group SPG, one IR pixel IPX and one color pixel CPX may be arranged in one diagonal direction, and two color pixels CPX may be arranged in the other diagonal direction. However, the example embodiments are not necessarily limited thereto, and the number of the IR pixels IPX and the color pixels CPX included in each sub-pixel group SPG, and a method of arranging at least one of the IR pixels IPX and the color pixels CPX in the sub-pixel group SPG may vary.

In some example embodiments, the colors of the second color filter of the second sub-pixel group SPG2 and the third color filter of the third sub-pixel group SPG3 may be the same. For example, the first color filter of the first sub-pixel group SPG1 may include the red color filter R, the fourth color filter of the fourth sub-pixel group SPG4 may include the cyan color filter Cy, and the second color filter and the third color filter of the second sub-pixel group SPG2 and the third sub-pixel group SPG3 may include the yellow color filters Y. However, the example embodiments are not necessarily limited thereto, and various arrangement methods of the color filters CF in addition to the pattern described with reference to FIG. 14B may be possible.

FIG. 14C is a diagram of the pixel array 110′ including the white layer W according to some example embodiments. Duplicate descriptions given above are omitted.

For example, each of the first sub-pixel group SPG1, the second sub-pixel group SPG2, the third sub-pixel group SPG3, and the fourth sub-pixel group SPG4 may include two IR pixels IPX and two color pixels CPX. However, the example embodiments are only an example, and the number of the IR pixels IPX and the color pixels CPX included in the sub-pixel group SPG is not necessarily limited thereto. In the sub-pixel group SPG, two IR pixels IPX may be arranged in one diagonal direction, and two color pixels CPX may be arranged in the other diagonal direction. However, the example embodiments are not necessarily limited thereto, and the number of the IR pixels IPX and the color pixels CPX included in each sub-pixel group SPG, and a method of arranging at least one of the IR pixels IPX and the color pixels CPX in the sub-pixel group SPG may vary.

The second filter of the IR pixel IPX and the third filter of the color pixel CPX included in the first sub-pixel group SPG1 may include the first color filter. The second filter of the IR pixel IPX and the third filter of the color pixel CPX included in the second sub-pixel group SPG2 may include the second color filter. The second filter of the IR pixel IPX and the third filter of the color pixel CPX included in the third sub-pixel group SPG3 may include the third color filter. The second filter of the IR pixel IPX and the third filter of the color pixel CPX included in the fourth sub-pixel group SPG4 may include the fourth color filter. Although FIG. 14C illustrates that the fourth filter of the color pixel CPX includes the IR filter IF, the example embodiments are not necessarily limited thereto, and the fourth filter may also include the color filter CF.

In some example embodiments, the colors of the second color filter of the second sub-pixel group SPG2 and the third color filter of the third sub-pixel group SPG3 may be the same. For example, the first color filter of the first sub-pixel group SPG1 may include the red color filter R, the fourth color filter of the fourth sub-pixel group SPG4 may include the blue color filter B, and the second color filter and the third color filter of the second sub-pixel group SPG2 and the third sub-pixel group SPG3 may include the white layer W. However, the example embodiments are not necessarily limited thereto, and various arrangement methods of the color filters CF in addition to the pattern described with reference to FIG. 14C may be possible.

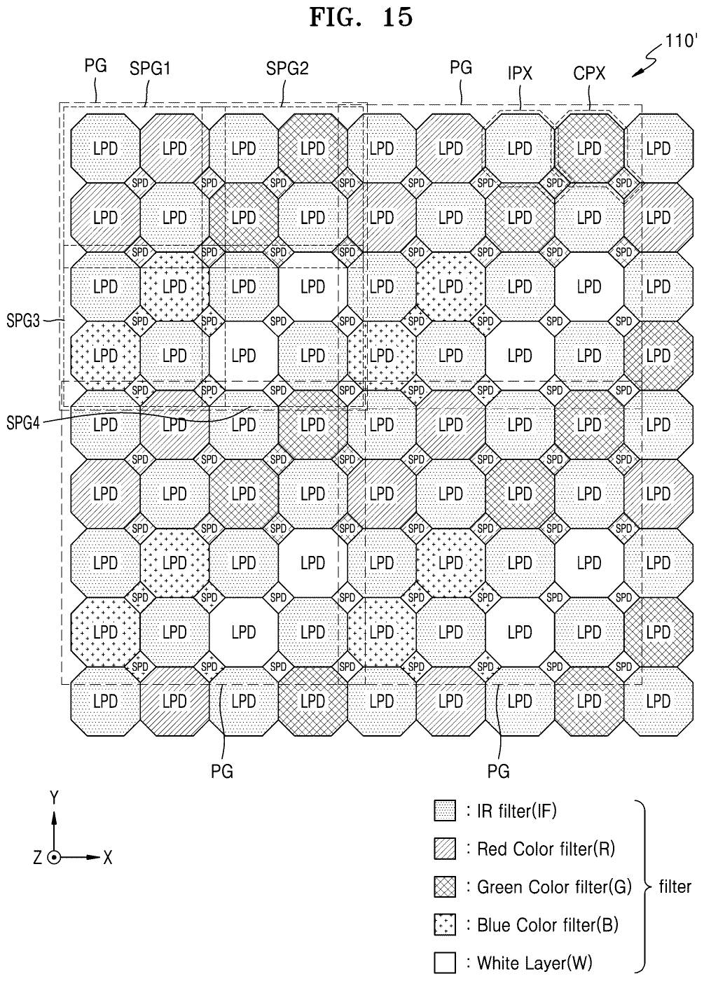

FIG. 15 is a diagram of the pixel array 110′ including the sub-pixel groups according to some example embodiments. Each of first through fourth sub-pixel groups SPG1 through SPG4 in FIG. 15 may include different color filters CF. Duplicate descriptions given with reference to FIG. 14A are omitted.

Referring to FIG. 15, colors of the color filters CF included in each of the first sub-pixel group SPG1, the second sub-pixel group SPG2, the third sub-pixel group SPG3, and the fourth sub-pixel group SPG4 may be different from each other. For example, the first color filter of the first sub-pixel group SPG1 may include the red color filter R, the second color filter of the second sub-pixel group SPG2 may include the green color filter G, the third color filter of the third sub-pixel group SPG3 may include the blue color filter B, and the fourth color filter of the fourth sub-pixel group SPG4 may include the white layer W. However, the example embodiments are not necessarily limited thereto, and various arrangement methods of the color filters CF in addition to the pattern described with reference to FIG. 15 may be possible.

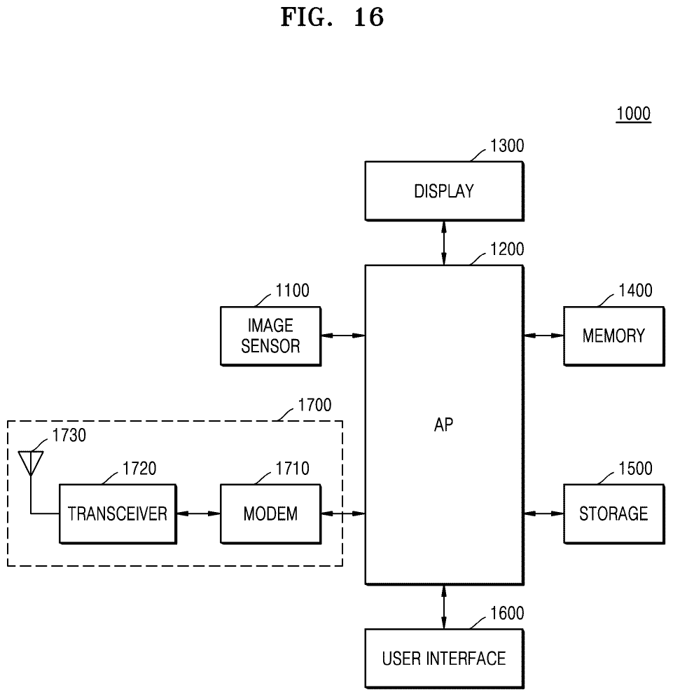

FIG. 16 is a block diagram of an electronic device 1000 according to some example embodiments.

Referring to FIG. 16, the electronic device 1000 according to some example embodiments may include an application processor (AP) 1200, an image sensor 1100, a display device 1300, a memory 1400, a storage 1500, a user interface 1600, and a wireless transceiver 1700. The descriptions of the image sensors according to some example embodiments of the inventive concepts described with reference to FIGS. 1 through 15 may be applied to the image sensor 1100.

The image sensor 1100 may be mounted on the electronic device 1000 having an image or light sensing function. For example, the electronic device 1000 may be provided as a component in a vehicle or the like, and the image sensor 1100 may be mounted on the electronic device 1000 provided as a component in the vehicle. However, the example embodiments are not limited thereto.

The image sensor 1100 may include a pixel array, and the pixel array may include the IR pixels IPX and the color pixels CPX. Each of the IR pixels IPX and the color pixels CPX may include the first photoelectric conversion element and the second photoelectric conversion element. The light-receiving area of the first photoelectric conversion element may be greater than the light-receiving area of the second photoelectric conversion element.

The IR pixel IPX may include the first filter arranged on the first photoelectric conversion element of the IR pixel IPX, and the second filter arranged on the second photoelectric conversion element of the IR pixel IPX. The first filter may include the IR filter IF which absorbs light in the infrared ray region. The second filter may include the color filter CF which absorbs light in the visible ray region. The IR pixel IPX may mean a pixel PX in which the IR filter IF is arranged above the first photoelectric conversion element.

The color pixel may include the third filter arranged on the first photoelectric conversion element of the color pixel CPX and the fourth filter arranged on the second photoelectric conversion element of the color pixel CPX. The third filter may include the color filter CF which absorbs light in the visible ray region. The fourth filter may include a filter which absorbs light in the infrared ray region and light in the visible ray region. The fourth filter may include one of the color filter CF and the IR filter IF. The color pixel CPX may mean a pixel PX in which the color filter CF is arranged above the first photoelectric conversion element.

In some example embodiments, a pixel array includes a plurality of pixels PX, and each of the plurality of pixels PX may include the IR pixel IPX. The color filter CF may be arranged in the second photodiode of each of the plurality of IR pixels PX, and the color filters CF may be arranged in various ways according to the use and characteristics of the image sensor 1100.

In some example embodiments, in the pixel array, a plurality of pixel groups PG may be repeatedly arranged, and each of the plurality of pixel groups PG may include at least one IR pixel IPX and at least one color pixel CF. For example, the pixel group PG may include two IR pixels IPX and two color pixels CF. However, the example embodiments are not limited thereto. The second filter of the IR pixel IPX and the third filter of the color pixel CPX may include the color filter CF, and the color filters CF may be arranged in various ways according to the use and characteristics of the image sensor 1100.

The AP 1200 may be provided as a system-on-chip (SoC) which controls the overall operation of the electronic device 1000 and drives an application program, an operating system, etc.

The AP 1200 may receive image data from the image sensor 1100.

The image sensor 1100 may generate image data such as image data, based on the received optical signal, and provide the generated image data to the AP 1200. The image data may also be referred to as the pixel value pdt. The image sensor 1100 may generate the image data based on light in the infrared ray region and light in the visible ray region.

The memory 1400 may be implemented as a volatile memory, such as dynamic random access memory (RAM) (DRAM) and static RAM (SRAM), or a resistive non-volatile memory, such as ferroelectric RAM (FeRAM), resistive RAM (RRAM), and phase change RAM (PRAM). The memory 1400 may store programs and/or data, which the AP 1200 processes or executes.

The storage 1500 may be implemented as a non-volatile memory, such as a NAND flash memory and resistive memory, and the storage 1500 may be provided as, for example, a memory card (a multi-media card (MMC), an embedded MMC (eMMC), a secure card (SD), and a micro SD), etc. The storage 1500 may store data and/or programs for execution algorithm controlling the image processing operation of the image sensor 1100, and the data and/or programs may be loaded into the memory 1400 when the image processing operation is performed. In some example embodiments, the storage 1500 may store output image data generated by the image sensor 1100, such as corrected image data or post-processed image data.

The user interface 1600 may be implemented as various devices capable of receiving a user input, such as a keyboard, a curtain key panel, a touch panel, a finger print sensor, and a microphone. The user interface 1600 may receive the user input, and provide a signal corresponding to the received user input to the AP 1200.

The wireless transceiver 1700 may include a transceiver 1720, a modem 1710, and an antenna 1730.

As described herein, any electronic devices and/or portions thereof according to any of the example embodiments may include, may be included in, and/or may be implemented by one or more instances of processing circuitry such as hardware including logic circuits; a hardware/software combination such as a processor executing software; or any combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a DRAM device, storing a program of instructions, and a processor (e.g., CPU) configured to execute the program of instructions to implement the functionality and/or methods performed by some or all of any devices, systems, modules, units, controllers, circuits, architectures, and/or portions thereof according to any of the example embodiments, and/or any portions thereof.

While the inventive concepts have been particularly shown and described with reference to embodiments thereof, it will be understood that various change in form and details may be made therein without departing from the spirit and scope of the following claims.

What is claimed is:

1. An image sensor comprising:
a pixel group including a plurality of unit pixels, each of the plurality of unit pixels comprising:
an infrared pixel comprising a first photoelectric conversion element (PD); and
a non-infrared pixel comprising a second PD having a smaller light-receiving area than the first PD in a plan view,
wherein the non-infrared pixel is configured to sense a visible light,
wherein a plurality of infrared pixels are arranged in a first direction and a second direction perpendicular to the first direction, and
wherein the non-infrared pixel is disposed diagonally to the infrared pixel in a third direction different from the first and second directions.

2. The image sensor of claim 1, wherein the non-infrared pixel is a color pixel configured to transmit at least one of light having a green visible wavelength, a red visible wavelength, a blue visible wavelength, and a yellow visible wavelength to the second PD.

3. The image sensor of claim 2, further comprising:
a substrate comprising a first surface and a second surface opposing the first surface;
a first isolation layer separating the infrared pixel in a first unit pixel of the plurality of unit pixels and the infrared pixel in a second unit pixel of the plurality of unit pixels and in contact with the second surface; and
a second isolation layer separating the infrared pixel in the first unit pixel and the non-infrared pixel in the first unit pixel,
wherein the second isolation layer is in contact with the second surface, and
wherein the image sensor is configured to receive the visible light through the second surface.

4. The image sensor of claim 3, wherein each of the first and second isolation layers is in contact with the first surface.

5. The image sensor of claim 4, wherein N number of the non-infrared pixels configured to transmit the light having the green visible wavelength to Number of second PDs,
wherein M number of the non-infrared pixels configured to transmit the light having the red visible wavelength to M number of second PDs,
wherein N and M are integers, and
wherein N is greater than M.

6. The image sensor of claim 5, wherein L number of the non-infrared pixels configured to transmit the light having the blue visible wavelength to L number of second PDs,
wherein L is an integer, and
wherein N is greater than L.

7. The image sensor of claim 1, wherein N number of the non-infrared pixels are color pixels and M number of the non-infrared pixels are white pixels,
wherein N and M are integers, and
wherein M is equal to or greater than N.

8. The image sensor of claim 7, wherein M number of the non-infrared pixels include a plurality of red pixels.

9. An image sensor comprising:
a pixel group comprising four unit pixels arranged in a 2×2 matrix, each of unit pixels in the four unit pixels comprising:
an infrared pixel comprising a first photoelectric conversion element (PD);
a non-infrared pixel comprising a second PD having a smaller light-receiving area than the first PD in a plan view,
wherein the four unit pixels comprising:
a first unit pixel;
a second unit pixel disposed directly adjacent to the first unit pixel in a first direction;
a third unit pixel disposed directly adjacent to the first unit pixel in a second direction; and
a fourth unit pixel disposed directly adjacent to the second unit pixel in the second direction,
wherein the non-infrared pixel is disposed diagonally to the infrared pixel in a third direction different from the first and second directions,
wherein the non-infrared pixel in the first unit pixel is configured to transmit a first color to the second PD in the first unit pixel,
wherein the non-infrared pixel in the second unit pixel is configured to transmit a second color to the second PD in the second unit pixel, and
wherein the second color is different from the first color.

10. The image sensor of claim 9, wherein the non-infrared pixel in the third unit pixel is configured to transmit the second color to the second PD in the third unit pixel.

11. The image sensor of claim 9, wherein the non-infrared pixel in the fourth unit pixel is configured to transmit a third color to the second PD in the fourth unit pixel, and
wherein the third color is different from the second color.

12. The image sensor of claim 10, further comprising:
a substrate comprising a first surface and a second surface opposing the first surface;
a first isolation layer separating the infrared pixel in the first unit pixel and the infrared pixel in the second unit pixel and in contact with the second surface; and
a second isolation layer separating the infrared pixel in the first unit pixel and the non-infrared pixel in the first unit pixel,
wherein the second isolation layer is in contact with the second surface, and
wherein the image sensor is configured to receive the visible light through the second surface.

13. The image sensor of claim 12, wherein each of the first and second isolation layers is in contact with the first surface.

14. The image sensor of claim 12, wherein each of the four unit pixels further comprising:
a driving transistor configured to output a first voltage corresponding to an amount of photocharges generated by the first PD and output a second voltage corresponding to an amount of photocharges generated by the second PD; and
a selection transistor connected to the driving transistor.

15. The image sensor of claim 14, wherein the first and second PDs in the first to fourth unit pixels are disposed on a first chip, wherein the driving transistor and the selection transistor are disposed on a second chip different from the first chip.

16. An image sensor comprising:
a first sub-pixel group comprising four unit pixels arranged in a 2×2 matrix, each of unit pixels in the four unit pixels comprising: 2×2
a first infrared pixel comprising a first photoelectric conversion element (PD);
a first non-infrared pixel comprising a second PD having a smaller light-receiving area than the first PD in a plan view,
wherein the four unit pixels comprising:
a first unit pixel;
a second unit pixel disposed directly adjacent to the first unit pixel in a first direction;
a third unit pixel disposed directly adjacent to the first unit pixel in a second direction; and
a fourth unit pixel disposed directly adjacent to the second unit pixel in the first direction,
wherein the first non-infrared pixel is disposed diagonally to the first infrared pixel in a third direction different from the first and second directions, and
wherein the first non-infrared pixels in the first to fourth unit pixels are configured to transmit a first color to the second PDs of the first to fourth unit pixels.

17. The image sensor of claim 16, further comprising:
a second sub-pixel group comprising four unit pixels arranged in the 2×2 matrix, each of unit pixels comprising:
a second infrared pixel comprising a third PD;
a second non-infrared pixel comprising a fourth PD having a smaller light-receiving area than the first PD in a plan view,
wherein the second non-infrared pixels in the second sub-pixel group are configured to transmit a second color to the fourth PDs in the second sub-pixel group, and
wherein the second color is different from the first color.

18. The image sensor of claim 17, wherein the second sub-pixel group is directly disposed adjacent to the first sub-pixel group in the first direction, and
wherein the second color is red.

19. The image sensor of claim 17, wherein the second sub-pixel group is directly disposed adjacent to the first sub-pixel group in the first direction, and wherein the second color is green.

20. The image sensor of claim 17, further comprising:
a substrate comprising a first surface and a second surface opposing the first surface; and
an isolation layer separating the infrared pixel in the first unit pixel and the infrared pixel in the second unit pixel and in contact with the first and second surfaces.
